(19) United States
(12) Patent Application Publication
(10) Pub. No.: US 2026/0024603 A1
(43) Pub. Date: Jan. 22, 2026

(54) MEMORY WITH DATA BUS (DQ) MAPPINGS BASED ON FAULT BOUNDARY REQUIREMENTS, AND ASSOCIATED SYSTEMS, DEVICES, AND METHODS

(71) Applicant: Micron Technology, Inc., Boise, ID (US)

(72) Inventors: Liang Chen, Allen, TX (US); Scott E. Smith, Plano, TX (US); Wesley W. Borie, Boise, ID (US); Garth N. Grubb, Boise, ID (US)

(21) Appl. No.: 19/272,996

(22) Filed: Jul. 17, 2025

Related U.S. Application Data
(60) Provisional application No. 63/673,663, filed on Jul. 19, 2024.

(51) Int. Cl. G11C 29/02; G11C 11/408; G11C 29/52

(52) U.S. Cl. CPC G11C 29/022; G11C 11/4087; G11C 29/52

(57) ABSTRACT

Memory with DQ mappings based on fault boundary requirements are described herein. In one embodiment, a memory device includes a memory array having a plurality of column planes, bank control circuitry including a plurality of sub-wordline drivers, and data path circuitry including a plurality of data busses (DQs) and data routing circuitry. Each sub-wordline driver can be associated with at least one column plane of the plurality of column planes. Furthermore, the data routing circuitry can be configured to couple each DQ of the plurality of DQs to a respective one of the plurality of column planes in accordance with a DQ map such that (i) each column plane of the plurality of column planes is coupled to a only one DQ at a time and (ii) bit errors resulting from a failure of one of the plurality of sub-wordline drivers occur on two DQs of a same nibble.

### CROSS-REFERENCE TO RELATED APPLICATION(S)

The present application claims priority to U.S. Provisional Patent Application No. 63/673,663, filed Jul. 19, 2024, the disclosure of which is incorporated herein by reference in its entirety.

### TECHNICAL FIELD

The present disclosure is generally related to semiconductor devices. For example, several embodiments of the present technology relate to memory devices that include DQ mappings that meet fault boundary requirements (e.g., to reduce the likelihood of uncorrectable errors and/or silent data corruption occurring within the memory devices as a result of memory defects).

### BACKGROUND

An electronic apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM), NAND memory, and/or high-bandwidth memory (HBM), can utilize electrical energy to store and access data.

With technological advancements in embedded systems and increasing applications, the market is continuously looking for faster, more efficient, and smaller devices. To meet market demands, the semiconductor devices are being pushed to the limit with various improvements. Improving devices, generally, may include increasing circuit density, increasing circuit capacity, increasing operating speeds (or otherwise reducing operational latency), increasing reliability, increasing data retention, reducing power consumption, increasing energy efficiency, or reducing manufacturing costs, among other metrics.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments depicted, but are for explanation and understanding only.

FIG. 1A is a block diagram schematically illustrating a memory system configured in accordance with various embodiments of the present technology.

FIG. 1B is a block diagram schematically illustrating a memory device configured in accordance with various embodiments of the present technology.

FIG. 1C is a simplified block diagram schematically illustrating components of the memory device of FIG. 1B.

FIG. 2 is a partially schematic diagram of a DQ map for a memory device operated in a X8 configuration, the DQ map and memory device configured in accordance with various embodiments of the present technology.

FIG. 3 is a partially schematic diagram of data routing circuitry that corresponds to the DQ map of FIG. 2 and that is configured in accordance with various embodiments of the present technology.

FIG. 4 is a partially schematic diagram of a DQ map for a memory device operated in a X4 configuration, the DQ map and the memory device configured in accordance with various embodiments of the present technology.

FIG. 5 is a partially schematic diagram of data routing circuitry that corresponds to the DQ map of FIG. 4 and that is configured in accordance with various embodiments of the present technology.

FIG. 6 is a table summarizing the DQ maps of FIGS. 2 and 4.

FIG. 7 is a partially schematic diagram of another DQ map for a memory device operated in a X8 configuration, the DQ map and the memory device configured in accordance with various embodiments of the present technology.

FIG. 8 is a partially schematic diagram of data routing circuitry that corresponds to the DQ map of FIG. 7 and that is configured in accordance with various embodiments of the present technology.

FIG. 9 is a partially schematic diagram of another DQ map for a memory device operated in a X4 configuration, the DQ map and the memory device configured in accordance with various embodiments of the present technology.

FIG. 10 is a partially schematic diagram of data routing circuitry that corresponds to the DQ map of FIG. 9 and that is configured in accordance with various embodiments of the present technology.

FIG. 11 is a table summarizing the DQ maps of FIGS. 7 and 9.

FIG. 12 is a flow diagram illustrating a method of operating a memory device in accordance with various embodiments of the present technology.

FIG. 13 is a block diagram of a system having a memory device configured in accordance with embodiments of the present technology.

### DETAILED DESCRIPTION

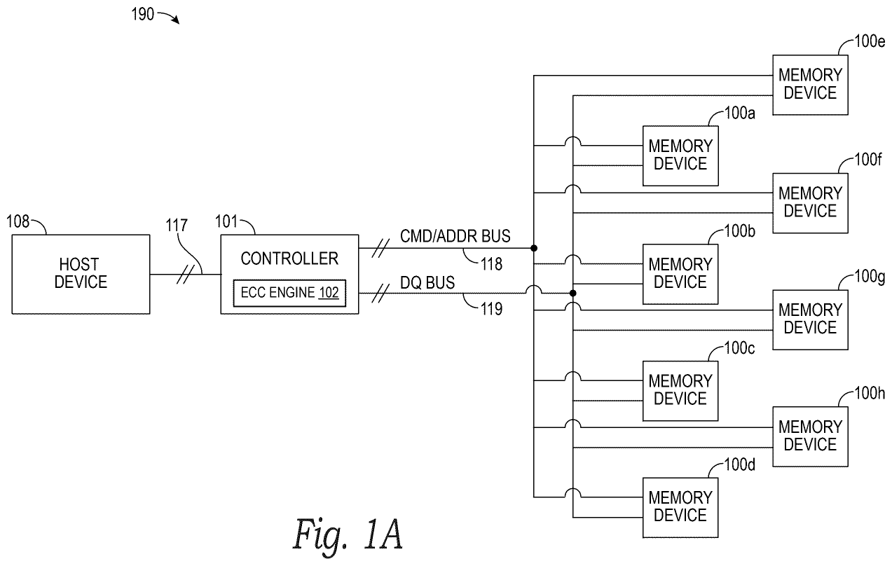

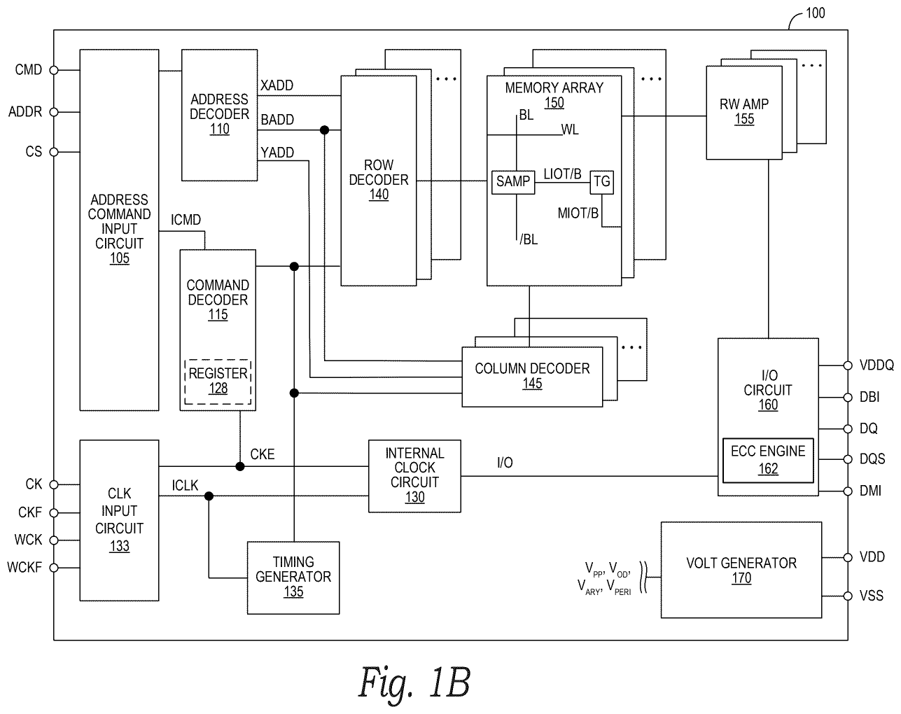

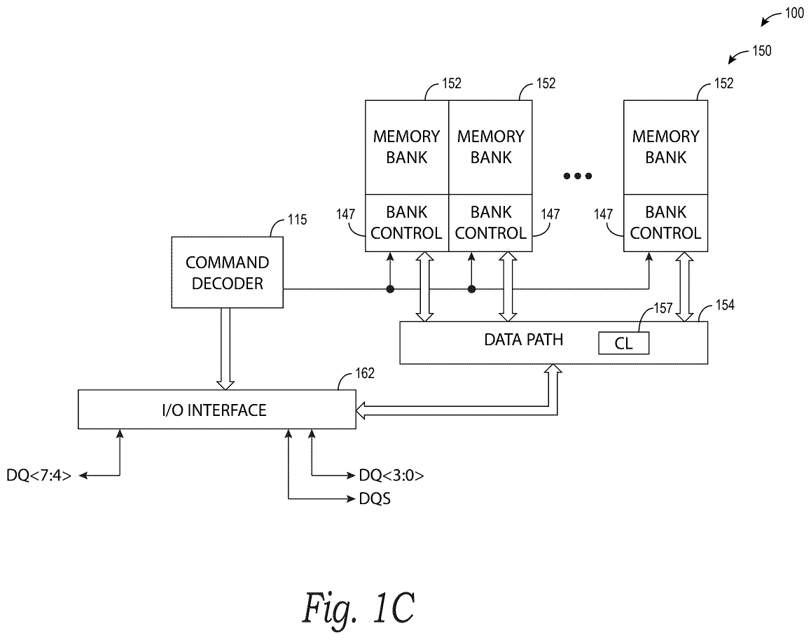

As discussed in greater detail below, the technology disclosed herein relates generally to DQ maps for memory devices. Each DQ map can specify assignments of data busses (DQs) to column planes of a memory array. In some embodiments, the assignments can be based at least in part on row address information received by the memory device. In these and other embodiments, the assignments can meet fault boundary requirements of error correction schemes of the memory devices to, for example, decrease a number of silent data corruption and/or uncorrectable error scenarios that can occur as a result of a memory defect (e.g., a column select failure, a sub-wordline failure, a su-wordline driver failure, etc.). Stated another way, the assignments of each DQ map configured in accordance with various embodiments of the present technology are expected to increase the likelihood that bit errors that occur on data paths/data busses as a result of a memory defect are detectable and/or correctable. A person skilled in the art will understand that the technology may have additional embodiments and that the technology may be practiced without several of the details of the embodiments described below with reference to FIGS. 1A-13.

In the illustrated embodiments below, memory devices and systems are primarily described in the context of devices incorporating DRAM storage media. Memory devices configured in accordance with other embodiments of the present technology, however, can include other types of memory devices and systems incorporating other types of storage media, including PCM, SRAM, FRAM, RRAM, MRAM, read only memory (ROM), erasable programmable ROM (EPROM), electrically erasable programmable ROM (EEROM), ferroelectric, magnetoresistive, and other storage media, including non-volatile, flash (e.g., NAND and/or NOR) storage media.

Dynamic random-access memory (DRAM) devices often organize data by data paths or data busses (DQs). For example, in double data rate fourth-generation (DDR4) DRAM devices, each DQ may be used to transfer eight (8) bits of data on each read or write access. Such DRAM devices commonly utilize a DQ map that assigns each DQ to one or more portions of a memory array. For example, an assignment in a DQ map may associate one or more DQs with one or more sub-wordline (SWL) drivers. The DQ map may be hard programmed into the memory device during manufacturing. Additionally, or alternatively, communication and/or control circuitry of the memory device may reference the DQ map when transmitting data to and from the memory array.

When writing data to or reading data from a memory device, the data can be written or read with one or more errors. Such errors may result from a memory defect, and some memory defects can cause multiple errors in the data. Examples of memory defects include weak sub-wordline (SWD ARM) fails, sub-wordline driver (SWD) fails, column redundancy (ColRed) fails, main wordline driver (FX) fails, and row redundancy (RowRed) fails. One or more of these memory defects can be caused by hardware malfunctions, manufacturing defects, and/or natural phenomena (e.g., neutron attacks).

Many memory devices employ error correction algorithms (e.g., error correction code (ECC)) to identify and/or correct errors in data written to and read from the memory devices. For example, error correction algorithms can organize data in symbols, and when an error occurs in one or more bits of a symbol, the error correction algorithms can be employed to detect and/or correct the bit(s) to restore the data in the symbol. In some cases, however, data errors may be undetectable or uncorrectable due to limitations in the error correction algorithms employed by a memory device. For example, many error correction algorithms include correction conditions that specify scenarios in which an error can be detected and/or corrected. As specific examples, many correction schemes include one or more of the following correction conditions: (1) a single DQ with all eight burst bits failing can be corrected; (2) two DQs with all burst bits failing can be corrected so long as the two DQs are not adjacent one another; (3) four DQs with failing bits can be corrected so long as the failing bits are from a same nibble of the burst; and/or (4) one random bit failing from each of four DQs can be corrected. Thus, if one or more errors occur that fall outside correction conditions specified by an error correction scheme, the error(s) may be undetectable or uncorrectable by the corresponding error correction algorithms. When an error occurs and is not detected/identified by error correction algorithms, the occurrence of the error is referred to herein as silent data corruption (SDC). When an error is detected and is not correctable by the error correction algorithms, the error is referred to herein as an uncorrectable error (UE).

Several correction conditions (and therefore non-correction conditions) can depend or be based on the DQ map employed by a memory device. Thus, to reduce a likelihood of SDC and UE scenarios, a DQ map may be designed and implemented so as to avoid or reduce the likelihood of non-correction conditions occurring. To this end, the present technology is generally directed to DQ maps that are each expected to reduce a number of non-correction conditions such that, were one or more errors to occur in data, the likelihood of the error(s) being undetected and/or uncorrectable is decreased. Stated another way, the present technology is generally directed to DQ maps that are each expected to increase a number of correction conditions such that, were one or more errors to occur in data, the likelihood of error correction algorithms detecting and/or correcting the error(s) is increased. When fewer SDC errors and/or fewer UEs occur within a memory device, memory device operation may become more reliable. Thus, memory device operation may improve overall based on how the reliability of a memory device may increase when using the various systems, devices, and methods described herein.

As described in greater detail below, DQ maps configured in accordance with various embodiments of the present technology can be designed and implemented to meet a fault boundary requirement. In some embodiments, the fault boundary requirement can include the following DQ mapping rule: DQs of a memory device are mapped in such a way that the likelihood of adjacent DQs failing together is reduced, minimized, or eliminated. For example, many error correction schemes employed by a memory device or system include a non-correction condition that specifies that if two adjacent DQs (e.g., DQ0 and DQ1) have bits that fail together, the error correction schemes are not able to correct the bit errors. Under such schemes, it would be better if non-adjacent DQs (e.g., (i) DQ0 and (ii) DQ2 or DQ3) have bits that fail together as the error correction schemes are able to correct such errors. As such, DQ maps configured in accordance with various embodiments of the present technology can be designed and implemented to (a) avoid or reduce the possibility of bits of two adjacent DQs failing together and/or (b) increase the probability that if bits of a first DQ were to fail with bits of a second DQ, the second DQ is non-adjacent to the first DQ.

Additionally, or alternatively, the fault boundary requirement can include the following DQ mapping rule: for a memory device operating in a configuration (e.g., a X8 configuration) with two or more nibbles (e.g., a first nibble including DQ0-DQ3, and a second nibble including DQ4-DQ7), DQs of the memory device are mapped in such a way that failures do not occur across a nibble boundary (e.g., failures do not occur in both the first nibble and the second nibble). For example, many error correction schemes employed by a memory device or system include a non-correction condition that specifies that if two DQs have bits that fail together and the two DQs belong to different nibbles such that the bit failures occur across a nibble boundary, the error correction schemes are not able to correct the bit errors. Under such schemes, it would be better if DQs (e.g., DQ0 and DQ2) of a same nibble (e.g., the first nibble described above) have bits that fail together than if DQs (e.g., DQ0 and DQ4) of different nibbles (e.g., the first nibble and the second nibble described above) have bits that fail together. As such, DQ maps configured in accordance with various embodiments of the present technology can be designed and implemented to isolate DQs of a first nibble from DQs of a second nibble to (a) avoid or reduce the possibility of two DQs belonging to different nibbles having bits that fail together and/or (b) increase the probability that if two DQs have bits that fail together, the two DQs belong to a same nibble.

DQ maps configured in accordance with various embodiments of the present technology are expected to offer several additional advantages. For example, DQ maps configured in accordance with several embodiments of the present technology are expected to reduce the likelihood of SDC and/or UE scenarios without increasing power or current consumption of the corresponding memory devices and systems. As another example, DQ maps configured in accordance with several embodiments of the present technology are expected to reduce the likelihood of SDC and UE scenarios without data routing circuitry that increases the size of the memory dies, devices, and systems.

FIG. 1A is a block diagram schematically illustrating a memory system 190 (e.g., a dual in-line memory module (DIMM)) configured in accordance with various embodiments of the present technology. In the illustrated embodiment, the memory system 190 includes a module or rank of memory devices 100 (identified individually as memory devices 100a-100h in FIG. 1A), a controller 101, and a host device 108. In some embodiments, the memory devices 100a-100h can be DRAM memory devices. For example, one or more of the memory devices 100a-100h can be double data rate fourth-generation (DDR4) memory devices or another generation (e.g., DDR5, DDR3, etc.) memory devices. Although illustrated with a single module/rank of eight memory devices 100a-100h in FIG. 1A, the memory system 190 can include a greater or lesser number of memory devices 100 and/or memory modules/ranks in other embodiments of the present technology. Well-known components of the memory system 190 have been omitted from FIG. 1A and are not described in detail below so as to avoid unnecessarily obscuring aspects of the present technology.

The memory devices 100a-100h can be connected to one or more electronic devices that are capable of utilizing memory for temporary or persistent storage of information, or a component thereof. For example, one or more of the memory devices 100a-100h can be operably connected to one or more host devices. As a specific example, the memory devices 100a-100h of the memory system 190 illustrated in FIG. 1A are connected to a host device 101 (also referred to herein as a “memory controller 101” or a “control circuit 101”) and to a host device 108.

The memory devices 100a-100h of FIG. 1A are operably connected to the memory controller 101 via a command/address (CMD/ADDR) bus 118 and a data (DQ) bus 119. As described in greater detail below with respect to FIG. 1B, the CMD/ADDR bus 118 and the DQ bus 119 can be used by the memory controller 101 to communicate commands, memory addresses, and/or data to the memory devices 100a-100h. In response, the memory devices 100a-100h can execute commands received from the memory controller 101. For example, in the event a write command is received from the memory controller 101 over the CMD/ADDR bus 118, the memory devices 100a-100h can receive data from the memory controller 101 over the data DQ bus 119 and can write the data to memory cells corresponding to memory addresses received from the memory controller 101 over the CMD/ADDR bus 118. As another example, in the event a read command is received from the memory controller 101 over the CMD/ADDR bus 118, the memory devices 100a-100h can output data to the memory controller 101 over the data DQ bus 119 from memory cells corresponding to memory addresses received from the memory controller 101 over the CMD/ADDR bus 118.

The host device 108 of FIG. 1A may be a computing device such as a desktop or portable computer, a server, a hand-held device (e.g., a mobile phone, a tablet, a digital reader, a digital media player), or some component thereof (e.g., a central processing unit, a co-processor, a dedicated memory controller, etc.). The host device 108 may be a networking device (e.g., a switch, a router, etc.); a recorder of digital images, audio, and/or video; a vehicle; an appliance; a toy; or any one of a number of other products. In one embodiment, the host device 108 may be connected directly to one or more of the memory devices 100a-100h (e.g., via a communications bus of signal traces (not shown)). Additionally, or alternatively, the host device 108 may be indirectly connected to one or more of the memory device 100a-100h (e.g., over a networked connection or through intermediary devices, such as through the memory controller 101 and/or via a communications bus 117 of signal traces).

In some embodiments, the memory system 190 can include one or more RAS features, such as ECC components. For example, as shown in FIG. 1A, the memory controller 101 of the memory system 190 can include a system-level ECC component 102, such as an ECC engine or circuit. In these and other embodiments, the host device 108 can include a system-level ECC component (not shown) in addition to or in lieu of the ECC component 102.

The ECC component 102 can be configured to generate ECC information based at least in part on (a) data to be written to one or more of the memory devices 100a-100h and/or (b) data read from the one or more memory devices 100a-100h. The ECC information can include parity bits or other data (e.g., single-bit error correction and double-bit error detection codes) that can be used to identify and/or correct errors (e.g., bit insertions, bit deletions, or a bit inversions/flips) in data written to or read from the memory devices 100a-100h. In some embodiments, the ECC component 102 calculates or generates ECC information when the memory controller 101 writes data to one or more of the memory devices 100a-100h of the memory system 190. The generated ECC information can be written to the memory devices 100a-100h in addition to the corresponding write data. For example, the generated ECC information can be stored in the same memory devices 100a-100h to which the memory controller 101 writes the corresponding data. In these and other embodiments, the generated ECC information can be stored in a different memory device 100 than the memory device(s) 100a-100h to which the memory controller 101 writes the corresponding data. For example, the memory devices 100a-100h can be used to store data (e.g., user data), and a ninth memory device 100 (not shown in FIG. 1A) can be used to store ECC information corresponding to the data stored in the other eight memory devices 100a-100h.

The ECC information can be used to identify and/or correct errors in data written to or read from the memory devices 100a-100h during subsequent read operations. In particular, as the memory controller 101 reads the data from the memory devices 100a-100h, the memory controller 101 can also retrieve the ECC information corresponding to the data. Upon receipt of the data from the memory devices 100a-100h, the ECC component 102 can (a) recalculate or regenerate the ECC information based on the read data and (b) compare the recalculated ECC information to the retrieved ECC information that was stored in the memory devices and calculated at the time the data was written to the memory devices 100a-100h. If the recalculated ECC information matches the retrieved ECC information, then the ECC component 102 can determine that there are no errors present in the corresponding data read from the memory devices 100a-100h. On the other hand, if the recalculated ECC information does not match the retrieved ECC information, the ECC component 102 (i) can determine that at least one error is present in the corresponding data read from the memory devices 100a-100h, and/or (ii) can use the recalculated ECC information and/or the retrieved ECC information to correct one or more of the errors.

As discussed in greater detail below with respect to FIG. 1B, one or more of the memory devices 100a-100h of the memory system 190 can include device- or die-level ECC components (not shown in FIG. 1A) in addition to or in lieu of the system-level ECC component 102. In embodiments including both the system-level ECC component 102 and a die-level ECC component on a memory device 100, the ECC component 102 and the die-level ECC component can operate in tandem. For example, when the memory controller 101 writes data to the memory device 100, the memory controller 101 can supply the memory device 100 with ECC calculated by the ECC component 102. The die-level ECC component included within the memory device 100 can (a) separately calculate ECC information corresponding to the data received from the memory controller 101 and (b) compare the ECC information calculated by the die-level ECC component to the ECC information calculated by the ECC component 102. If the two sets of ECC information match, then the die-level ECC component can determine that there are no errors present in the corresponding data received from the memory controller 101. On the other hand, if the two sets of ECC information do not match, then the die-level ECC component can (i) determine that at least one error is present in the corresponding data received from the memory controller 101, and/or (ii) can use one or both of the sets of ECC information to correct one or more of the errors before writing the data to a memory array of the memory device 100.

As another example, when the memory controller 101 reads data from a memory device 100, the die-level ECC component included in the memory device 100 can calculate ECC information corresponding to the read data and supply the ECC information to the memory controller 101 along with the read data. In turn, the ECC component 102 can (a) separately calculate ECC information corresponding to the data received from the memory device 100 and (b) compare the ECC information calculated by the ECC component 102 to the ECC information calculated by the die-level ECC component. If the two sets of ECC information match, then the ECC component 102 can determine that there are no errors present in the corresponding data received from the memory device 100. On the other hand, if the two sets of ECC information do not match, then the ECC component 102 (i) can determine that at least one error is present in the corresponding data received from the memory device 100, and/or (ii) can use one or both of the sets of ECC information to correct one or more of the errors in the read data (e.g., before supplying the read data to the host device 108).

FIG. 1B is a block diagram schematically illustrating a memory device 100 configured in accordance with various embodiments of the present technology. In some embodiments, the memory device 100 may include a memory die (e.g., a single memory die, only one memory die) or multiple memory dies. In embodiments in which the memory device 100 includes multiple memory dies, the memory dies may be arranged in a stack (e.g., a three-dimensional stack (3DS)), may be laterally offset from one another, or may positioned in another suitable arrangement. In these and other embodiments, the memory device 100 may be a DRAM device, such as a DDR4 (or other generation) DRAM device.

The memory device 100 may include an array of memory cells, such as memory array 150. The memory array 150 may include a plurality of banks (e.g., banks 0-15 in the example of FIG. 1B), and each bank may include a plurality of wordlines (WL), a plurality of bit lines (BL), and a plurality of memory cells (e.g., m×n memory cells) arranged at intersections of the wordlines (e.g., m wordlines, which may also be referred to as rows) and the bit lines (e.g., n bit lines, which may also be referred to as columns). Each wordline of the plurality may be coupled with a corresponding wordline driver (WL driver) configured to control a voltage of the wordline during memory operations.

Memory cells can include any one of a number of different memory media types, including capacitive, phase change, magnetoresistive, ferroelectric, or the like. In some embodiments, a portion of the memory array 150 may be configured to store ECC information, such as ECC parity bits (ECC check bits) or codes. The selection of a wordline WL may be performed by a row decoder 140, and the selection of a bit line BL may be performed by a column decoder 145. Sense amplifiers (SAMP) may be provided for corresponding bit lines BL and connected to at least one respective local I/O line pair (LIOT/B), which may in turn be coupled to at least one respective main I/O line pair (MIOT/B), via transfer gates (TG), which can function as switches. The memory array 150 may also include plate lines and corresponding circuitry for managing their operation.

The memory device 100 may employ a plurality of external terminals that include command and address terminals coupled to a command bus and an address bus (e.g., the CMD/ADDR bus 118 of FIG. 1A) to receive command signals CMD and address signals ADDR, respectively. The memory device may further include a chip select terminal to receive a chip select signal CS, clock terminals to receive clock signals CK and CKF, data clock terminals to receive data clock signals WCK and WCKF, data terminals DQ, RDQS, DBI (for data bus inversion function), and DMI (for data mask inversion function), power supply terminals VDD, VSS, and VDDQ.

The power supply terminals may be supplied with power supply potentials VDD and VSS. These power supply potentials VDD and VSS can be supplied to an internal voltage generator circuit 170. The internal voltage generator circuit 170 can generate various internal potentials VPP, VOD, VARY, VPERI, and the like based on the power supply potentials VDD and VSS. The internal potential VPP can be used in the row decoder 140, the internal potentials VOD and VARY can be used in the sense amplifiers included in the memory array 150, and the internal potential VPERI can be used in many other circuit blocks.

The power supply terminals may also be supplied with power supply potential VDDQ. The power supply potential VDDQ can be supplied to the input/output circuit 160 together with the power supply potential VSS. The power supply potential VDDQ can be the same potential as the power supply potential VDD in some embodiments of the present technology. The power supply potential VDDQ can be a different potential from the power supply potential VDD in other embodiments of the present technology. The dedicated power supply potential VDDQ can be used for the input/output circuit 160 so that power supply noise generated by the input/output circuit 160 does not propagate to the other circuit blocks.

The clock terminals and data clock terminals may be supplied with external clock signals and complementary external clock signals. The external clock signals CK, CKF, WCK, WCKF can be supplied to a clock input circuit 133. The CK and CKF signals can be complementary, and the WCK and WCKF signals can also be complementary. Complementary clock signals can have opposite clock levels and transition between the opposite clock levels at the same time. For example, when a clock signal is at a low clock level a complementary clock signal is at a high level, and when the clock signal is at a high clock level the complementary clock signal is at a low clock level. Moreover, when the clock signal transitions from the low clock level to the high clock level the complementary clock signal transitions from the high clock level to the low clock level, and when the clock signal transitions from the high clock level to the low clock level the complementary clock signal transitions from the low clock level to the high clock level.

Input buffers included in the clock input circuit 133 can receive the external clock signals. For example, when enabled by a CKE signal from the command decoder 115, an input buffer can receive the CK and CKF signals and the WCK and WCKF signals. The clock input circuit 133 can receive the external clock signals to generate internal clock signals ICLK. The internal clock signals ICLK can be supplied to an internal clock circuit 130. The internal clock circuit 130 can provide various phase and frequency controlled internal clock signals based on the received internal clock signals ICLK and a clock enable signal CKE from the command decoder 115.

For example, the internal clock circuit 130 can include a clock path (not shown in FIG. 1B) that receives the internal clock signal ICLK and provides various clock signals to the command decoder 115. The internal clock circuit 130 can further provide input/output (I/O) clock signals. The I/O clock signals can be supplied to an input/output circuit 160 and can be used as a timing signal for determining an output timing of read data and the input timing of write data. The I/O clock signals can be provided at multiple clock frequencies so that data can be output from and input to the memory device 100 at different data rates. A higher clock frequency may be desirable when high memory speed is desired. A lower clock frequency may be desirable when lower power consumption is desired. The internal clock signals ICLK can also be supplied to a timing generator 135 and thus various internal clock signals can be generated.

The command terminals and address terminals may be supplied with an address signal and a bank address signal from outside the memory device 100. The address signal and the bank address signal supplied to the address terminals can be transferred, via input buffers of a command/address input circuit 105, to an address decoder 110. The address decoder 110 can receive the address signals and supply a decoded row address signal (XADD) to the row decoder 140 (which may be referred to as a row driver), and a decoded column address signal (YADD) to the column decoder 145 (which may be referred to as a column driver). The address decoder 110 can also receive the bank address portion of the ADDR input and supply the decoded bank address signal (BADD) and supply the bank address signal to both the row decoder 140 and the column decoder 145.

The command and address terminals may be supplied with command signals CMD, address signals ADDR, and chip select signals CS, from a memory controller. The command signals may represent various memory commands from the memory controller (e.g., refresh commands, activate commands, precharge commands, access commands, which can include read commands and write commands). The select signal CS may be used to select the memory device 100 to respond to commands and addresses provided to the command and address terminals. When an active CS signal is provided to the memory device 100, the commands and addresses can be decoded and memory operations can be performed. The command signals CMD may be provided as internal command signals ICMD to a command decoder 115 via the command/address input circuit 105.

The command decoder 115 may include circuits to decode the internal command signals ICMD to generate various internal signals and commands for performing memory operations, for example, a row command signal to select a wordline and a column command signal to select a bit line. Other examples of memory operations that the memory device 100 may perform based on decoding the internal command signals ICMD includes a refresh command (e.g., re-establishing full charges stored in individual memory cells of the memory array 150), an activate command (e.g., activating a row in a particular bank, in some cases for subsequent access operations), or a precharge command (e.g., deactivating the activated row in the particular bank). The internal command signals can also include output and input activation commands, such as clocked command CMDCK (not shown in FIG. 1B).

The command decoder 115, in some embodiments, may further include one or more registers 128 for tracking various counts and/or values (e.g., counts of refresh commands received by the memory device 100 or self-refresh operations performed by the memory device 100) and/or for storing various operating conditions for the memory device 100 to perform certain functions, features, and modes (or test modes). As such, in some embodiments, the registers 128 (or a subset of the registers 128) may be referred to as mode registers. Additionally, or alternatively, the memory device 100 may include registers 128 as a separate component outside of the command decoder 115. In some embodiments, the registers 128 may include multi-purpose registers (MPRs) configured to write and/or read specialized data to and/or from the memory device 100.

When a read command is issued to a bank with an open row and a column address is timely supplied as part of the read command, read data can be read from memory cells in the memory array 150 designated by the row address (which may have been provided as part of the activate command identifying the open row) and column address. The read command may be received by the command decoder 115, which can provide internal commands to an input/output circuit 160 so that read data can be output from the data terminals DQ, RDQS, DBI, and DMI via read/write amplifiers 155 and the input/output circuit 160 according to the RDQS clock signals. The read data may be provided at a time defined by read latency information RL that can be programmed in the memory device 100, for example, in a mode register (e.g., one or more of the registers 128). The read latency information RL can be defined in terms of clock cycles of the CK clock signal. For example, the read latency information RL can be a number of clock cycles of the CK signal after the read command is received by the memory device 100 when the associated read data is provided.

When a write command is issued to a bank with an open row and a column address is timely supplied as part of the write command, write data can be supplied to the data terminals DQ, DBI, and DMI according to the WCK and WCKF clock signals. The write command may be received by the command decoder 115, which can provide internal commands to the input/output circuit 160 so that the write data can be received by data receivers in the input/output circuit 160, and supplied via the input/output circuit 160 and the read/write amplifiers 155 to the memory array 150. The write data may be written in the memory cell designated by the row address and the column address. The write data may be provided to the data terminals at a time that is defined by write latency WL information. The write latency WL information can be programmed in the memory device 100, for example, in a mode register (e.g., one or more of the registers 128). The write latency WL information can be defined in terms of clock cycles of the CK clock signal. For example, the write latency information WL can be a number of clock cycles of the CK signal after the write command is received by the memory device 100 when the associated write data is received.

As discussed above, the memory device 100 can include one or more RAS features, such as ECC components. For example, as shown in FIG. 1B, the input/output circuit 160 includes a die-level ECC component 162, such as an ECC engine or circuit. The memory device 100 can include the ECC component 162 in addition to or in lieu of a system-level ECC component (e.g., the ECC component 102 of FIG. 1A). Although shown with the ECC component 162 as part of the input/output circuit 160 in FIG. 1B, the memory device 100 may include the ECC component 162 as a separate component outside of the input/output circuit 160 in other embodiments.

Similar to the ECC component 102 of FIG. 1A, the ECC component 162 of FIG. 1B can be configured to generate ECC information based at least in part on (a) data to be written to the memory array 150 of the memory devices 100 and/or (b) data read from the memory array 150 of the memory device 100. The ECC information calculated by the ECC component 162 can include parity bits or other data (e.g., single-bit error correction and double-bit error detection codes) that can be used to identify and/or correct errors (e.g., bit insertions, bit deletions, or a bit inversions/flips) in data written to or read from the memory array 150. In some embodiments, the ECC component 162 calculates or generates ECC information when the memory device 100 receives data to be written to the memory array 150. The generated ECC information can be written to the memory array 150 (e.g., to a portion of the memory array 150 configured to store ECC information) in addition to the corresponding write data.

The ECC information can be used to identify and/or correct errors in data written to or read from the memory array 150 during subsequent read operations. In particular, as data is read from the memory array 150, the memory device 100 can also retrieve the ECC information corresponding to the read data. Upon receipt of the read data, the ECC component 162 can (a) recalculate or regenerate the ECC information based on the read data and (b) compare the recalculated ECC information to the retrieved ECC information that was stored in the memory array 150 and calculated at the time the data was written to the memory array 150. If the recalculated ECC information matches the retrieved ECC information, then the ECC component 162 can determine that there are no errors present in the corresponding data read from the memory array 150. On the other hand, if the recalculated ECC information does not match the retrieved ECC information, the ECC component 102 (i) can determine that at least one error is present in the corresponding data read from the memory array 150, and/or (ii) can use the recalculated ECC information and/or the retrieved ECC information to correct one or more of the errors (e.g., before transmitting the data to the memory controller 101 and/or the host device 108 of FIG. 1A).

Additionally, or alternatively, the ECC component 162 can be operated in tandem with the system-level ECC component 102 of FIG. 1A, as discussed above. For example, when the ECC component 162 receives data to be written to the memory array 150 along with ECC information calculated by the ECC component 102, the ECC component 162 can (a) separately calculate ECC information corresponding to the received data and (b) compare the ECC information calculated by the ECC component 162 to the ECC information calculated by the ECC component 102 to determine whether errors are present in the corresponding data received from the memory controller 101. If errors are present, the ECC component 162 can use one or both of the sets of ECC information to correct one or more of the errors before writing the received data to the memory array 150.

As another example, the ECC component 162 can calculate ECC information for data read from the memory array 150. The read data and the corresponding ECC information calculated by the ECC component 162 can be transmitted to memory controller 101 of FIG. 1A. In turn, the system-level ECC component 102 can (a) separately calculate ECC information corresponding to the read data and (b) compare the ECC information calculated by the ECC component 102 to the ECC information calculated by the ECC component 162 to determine whether errors are present in the corresponding data received from the memory device 100. If errors are present, the ECC component 102 can use one or both of the sets of ECC information to correct one or more of the errors (e.g., before transmitting the read data to the host device 108).

FIG. 1C is a simplified block diagram schematically illustrating components of the memory device 100 of FIG. 1B. In particular, the memory device 100 is shown with the command decoder 115, a number of memory banks 152 of the memory array 150, data path circuitry 154, and an input/output (I/O) interface 162 configured to exchange (e.g., receive and transmit) signals with external devices. The command decoder 115 can decode commands, such as read commands, mode-register set commands, activate commands, or the like, and can provide access to a particular memory bank 152 corresponding to the command. In some embodiments, each memory bank 152 includes or is associated with a bank control block 147 that provides necessary decoding (e.g., via a row decoder and/or a column decoder), as well as other operations, such as timing control and data control, to facilitate the execution of commands to and from the memory bank 152.

Data can be sent to and from the memory device 100 utilizing the command and clocking signals discussed above with reference to FIG. 1B and by transmitting and receiving data signals through the I/O interface 162. Internally, the data can be sent to or retrieved from the memory banks 152 of the memory device 100 over data path circuitry 154. The data path circuitry 154 can include a plurality of bi-directional data buses and data routing circuitry. Data I/O signals (also referred to herein as “DQ signals”) are generally transmitted and received via one or more bi-directional data busses (also referred to herein as “DQs”). In the illustrated embodiment, the DQs (and therefore DQ signals transmitted thereon) are divided into a first (or lower) nibble (DQ0-DQ3, or DQ<3:0>) and a second (or upper) nibble (DQ4-DQ7, or DQ<7:4>). Collectively, the first and second nibbles can correspond to bytes of DQ signals.

In the illustrated embodiment, the memory device 100 can utilize data strobe signals DQS (e.g., to permit high data rates within the memory device 100). For example, for write commands, the data strobe signals DQS can be used as clock signals to capture corresponding data transmitted to the memory device from a memory controller or host device operably coupled to the memory device 100. Continuing with this example, for write commands, the data strobe signals DQS can be driven by the memory controller or the host device sending the data. As another example, for read commands, the data strobe signals DQS can be output from the memory device 100 with a predetermined pattern (e.g., that is usable by a memory controller or host device operably coupled to the memory device 100 to capture data transmitted to the memory controller or the host device from the memory device 100). Continuing with this example, the data strobe signals DQS can be driven by the memory device 100 for (or in response to) read commands.

The memory device 100 may employ a DQ map that assigns DQs to one or more sub-wordline (SWL) drivers. In some embodiments, all or a subset of the DQ map may be hard programmed into the memory device 100 during manufacturing. In these and other embodiments, all or a subset of the DQ map may be implemented or programmed using software or control logic. For example, in some embodiments, the data path circuitry 154 can include control logic 157 and/or data routing circuitry. The control logic 157 can include switching logic circuitry, control circuitry, or the like, that operates in response to control signals. For example, the control logic 157 can include multiplexing circuitry, hard programmed routing (e.g., wires), or the like. The control signals can be generated by the command decoder 115, processing circuitry of the control logic 157, or other suitable signal generation circuitry (e.g., with reference to or based on the DQ map). In operation, data pathways of the data path circuitry 154 can, responsive to the control signals, be programmed by the control logic 157 to implement routing changes between the I/O interface 165 and one or more of the memory banks 152 (e.g., corresponding to activation of one or more of the memory banks 152).

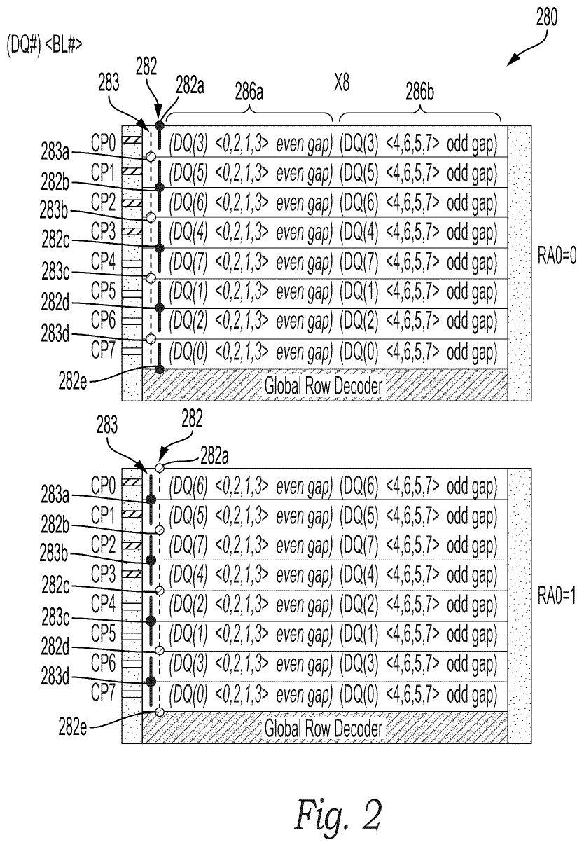

As discussed above, data errors can occur when writing data to or reading data from one or more of the memory banks 152 of the memory array 150. Some of these errors may be detectable and correctable by error correction operations (e.g., error correction code (ECC)) implemented by, for example, device-level or die-level ECC components (e.g., the ECC components 162 of FIG. 1B) and/or by system-level ECC components (e.g., the ECC components 102 of FIG. 1A). Depending at least in part on the DQ map implemented by the memory device 100, others of these errors may not be detectable or correctable by the device-level, die-level, and/or system-level ECC components. Therefore, example DQ maps configured in accordance with various embodiments of the present technology are described in detail below with reference to FIGS. 2-12. Each of these DQ maps are expected to reduce the likelihood of SDC and/or UE scenarios occurring (e.g., due to memory defects) within the memory device. In turn, each of these DQ maps are expected to improve memory device and/or memory system operation by improving reliability, uptime, and/or resource allocations (e.g., by enabling more computing resources to be used for performing non-ECC operations).

FIG. 2 is a partially schematic diagram of a DQ map 280 configured in accordance with various embodiments of the present technology. In some embodiments, the DQ map 280 can be employed by a memory device operated in a X8 configuration. For example, the DQ map 280 can be employed by a memory device (e.g., a DDR4 DRAM memory device) having a first (or lower) nibble including data busses DQ0-DQ3 and a second (or upper) nibble including data busses DQ4-DQ7. As described in greater detail below, the DQ map 280 can assign each of the eight data busses DQ0-DQ7 to one of eight column planes CP0-CP7.

In some embodiments, each of the column planes CP0-CP7 can include 64 columns. When a read or write command is received, one of the 64 columns in each column plane can be selected for each of eight column select signals issued with the read or write command. As each column select signal accesses eight bits of data in memory, each column cycle (each read or write command) can access 64 bits of parallel data (e.g., eight column select signals×eight accessed bits) across the eight data busses DQ0-DQ7.

In the illustrated embodiment, the column planes CP0-CP7 are associated with a first wordline 282 and a second wordline 283. The first wordline 282 can be used to read data from, or write data to, the column planes CP0-CP7 when a row address signal RAO received by the memory device is low (e.g., 0). The second wordline 283 can be used to read data from, or write data to, the column planes CP0-CP7 when the row address signal RAO is high (e.g., 1).

The first wordline 282 can be divided into sub-wordlines 282a-282e, and the second wordline 283 can be divided into sub-wordlines 283a-283d. Each of the sub-wordlines 282a-282e and 283a-283d can correspond to a respective sub-wordline driver. The sub-wordline drivers can control data transmission to and from respective ones of the column planes CP0-CP7. For example, when the row address signal RAO is low (e.g., 0), a sub-wordline driver corresponding to the sub-wordline 282b can be used to activate the sub-wordline 282b to access data stored to column planes CP1 and/or CP2. As another example, when the row address signal RAO is high (e.g., 1), a sub-wordline driver corresponding to the sub-wordline 283a can be used to activate the sub-wordline 283a to access data stored to column plane CP1, and a sub-wordline driver corresponding to the sub-wordline 283b can be used to activate the sub-wordline 283b to access data stored to column plane CP2. As still another example, when the row address signal RAO is low (e.g., 0) and the first wordline 282 is fired globally, the sub-wordlines 282a-282e can be activated to output data from all or a subset of the column planes CP0-CP7 in parallel. Similarly, when the row address signal RAO is high (e.g., 1) and the second wordline 283 is fired globally, the sub-wordlines 283a-283d can be activated to output data from all or a subset of the column planes CP0-CP7 in parallel.

As discussed above, memory defects can cause errors in data written to or read from a memory array of a memory device. For example, when (i) a sub-wordline driver and/or (ii) one or both arms of a sub-wordline fail, the corresponding one(s) of the column planes CP0-CP7 can output data with errors. As discussed above, in some error correction schemes, errors occurring in bits of a single DQ can be detected and/or corrected easier than errors occurring in bits of multiple (e.g., two or more) DQs. Similarly, errors occurring in bits of two DQs can be detected and/or corrected easier than errors occurring in bits of more than two (e.g., three, four, or more) DQs. Additionally, or alternatively, the likelihood of detecting and/or correcting errors occurring in two DQs can be higher when the two DQs are non-adjacent DQs and/or of a same nibble.

As described in greater detail below with reference to FIG. 6, the DQ map 280 is therefore designed such that the data busses DQ0-DQ7 are assigned to the column planes CP0-CP7 in a specific arrangement that is expected to, in the event of a memory defect, (a) reduce and/or minimize a total number of DQs having bits with errors; (b) increase the likelihood that if errors occur in bits of two DQs, the two DQs are not adjacent one another; and/or (c) increase the likelihood that if errors occur in bits of two DQs, the two DQs are of a same nibble. More specifically, when the row address signal RAO is low (e.g., 0), data path circuitry of a memory device can be used to route (i) data bus DQ3 into column plane CP0; (ii) data bus DQ5 into column plane CP1; (iii) data bus DQ6 into column plane CP2; (iv) data bus DQ4 into column plane CP3; (v) data bus DQ7 into column plane CP4; (vi) data bus DQ1 into column plane CP5; (vii) data bus DQ2 into column plane CP6; and (viii) data bus DQ0 into column plane CP7. On the other hand, when the row address signal RAO is high (e.g., 1), data path circuitry of the memory device can be used to route (i) data bus DQ6 into column plane CP0; (ii) data bus DQ5 into column plane CP1; (iii) data bus DQ7 into column plane CP2; (iv) data bus DQ4 into column plane CP3; (v) data bus DQ2 into column plane CP4; (vi) data bus DQ1 into column plane CP5; (vii) data bus DQ3 into column plane CP6; and (viii) data bus DQ0 into column plane CP7.

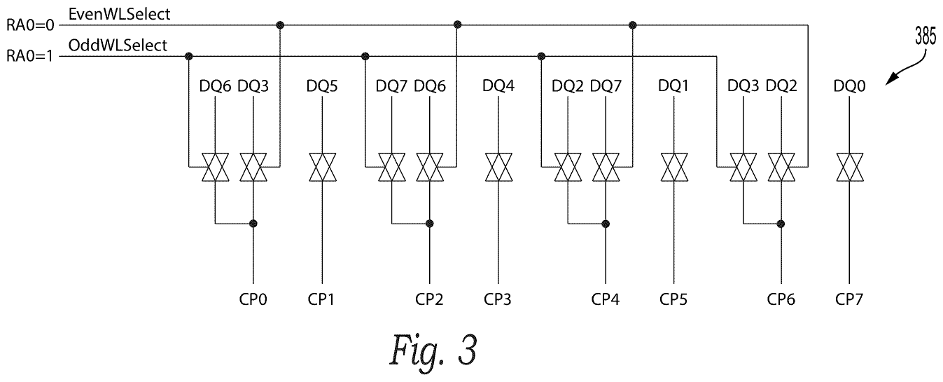

FIG. 3 is a partially schematic diagram of data routing circuitry 385 that corresponds to the DQ map 280 of FIG. 2 and that is configured in accordance with various embodiments of the present technology. In some embodiments, the data routing circuitry can be an example of the control logic 157 of FIG. 1C or of other circuitry configured in accordance with various embodiments of the present technology. As shown in FIG. 3, a state of the row address signal RAO is used to select (a) which of the data bus DQ6 or the data bus DQ3 is routed to the column plane CP0; (b) which of the data bus DQ7 or the data bus DQ6 is routed to the column plane CP2; (c) which of the data bus DQ2 or the data bus DQ7 is routed to the column plane CP4; and (d) which of the data bus DQ3 or the data bus DQ2 is routed to the column plane CP6. In the illustrated embodiment, regardless of the state of the row address signal RAO, the data bus DQ5 is routed to the column plane CP1, the data bus DQ4 is routed to the column plane CP3, the data bus DQ1 is routed to the column plane CP5, and the data bus DQ0 is routed to the column plane CP7.

Referring again to FIG. 2, bitlines BL0-BL7 of each of the data busses DQ0-DQ7 can be assigned to (or associated with) an even sense amp stripe 286a or an odd sense amp stripe 286b. More specifically, in the illustrated embodiment, bitlines BL0, BL2, BL1, and BL3 of each of the data busses DQ0-DQ7 can be assigned to the even sense amp stripe 286a. In addition, bitlines BL4, BL6, BL5, and BL7 of each of the data busses DQ0-DQ7 can be assigned to the odd sense amp stripe 286b.

The DQ map 280 of FIG. 2 also illustrates a column redundancy repair scheme that can be employed by a memory device. In particular, as shown by the small rectangles illustrated to the right of the column plane CP0-CP3 labels in FIG. 2, if one of column planes CP0-CP3 are repaired with a redundant column, then the column repair is repeated across the other three of the column planes CP0-CP3. Similarly, as shown by the small rectangles illustrated to the right of the column plane CP4-CP7 labels in FIG. 2, if one of the column planes CP4-CP7 are repaired with a redundant column, then the column repair is repeated across the other three of the column planes CP4-CP7.

Specific advantages of the DQ bus assignments shown in the DQ map 280 of FIG. 2 are described in greater detail below with reference to FIG. 6.

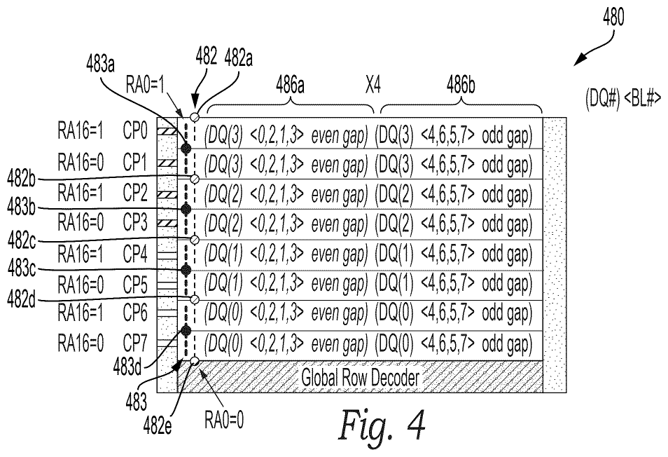

FIG. 4 is a partially schematic diagram of a DQ map 480 configured in accordance with various embodiments of the present technology. In some embodiments, the DQ map 480 can be employed by a memory device operated in a X4 configuration. For example, the DQ map 480 can be employed by a memory device (e.g., a DDR4 DRAM memory device) having a nibble including four data busses DQ0-DQ3. The memory device can be an example of the memory device described above with reference to FIG. 2 (e.g., the memory device can be selectively operated in the X8 configuration or the X4 configuration), or the memory device can be an example of other memory devices configured in accordance with various embodiments of the present technology. As described in greater detail below, the DQ map 480 can assign each of the four data busses DQ0-DQ3 to two of eight column planes CP0-CP7.

In some embodiments, each of the column planes CP0-CP7 can include 64 columns. When a read or write command is received, one of the 64 columns in four of the column planes can be selected for each of eight column select signals issued with the read or write command. As each column select signal accesses four bits of data in memory, each column cycle (each read or write command) can access 32 bits of parallel data (e.g., eight column select signals×four accessed bits) across the four data busses DQ0-DQ3. As described in greater detail below, which four of the column planes are accessed for a read or write command can be based at least in part on a state of a row address signal RA16.

In the illustrated embodiment, the column planes CP0-CP7 are associated with a first wordline 482 and a second wordline 483. The first wordline 482 can be used to read data from, or write data to, the column planes CP0-CP7 when a row address signal RAO received by the memory device is low (e.g., 0). The second wordline 483 can be used to read data from, or write data to, the column planes CP0-CP7 when the row address signal RAO is high (e.g., 1). In embodiments in which the DQ map 280 of FIG. 2 and the DQ map of 380 of FIG. 3 can be employed by the same memory device, the first wordline 482 can be the first wordline 282 of FIG. 2 and/or the second wordline 483 can be the second wordline 283 of FIG. 2.

The first wordline 482 can be divided into sub-wordlines 482a-482e, and the second wordline 483 can be divided into sub-wordlines 483a-483d. Each of the sub-wordlines 482a-482e and 483a-483d can correspond to a respective sub-wordline driver. The sub-wordline drivers can control data transmission to and from respective ones of the column planes CP0-CP7. For example, when the row address signal RAO is low (e.g., 0) and row address signal RA16 is low (e.g., 0), a sub-wordline driver corresponding to the sub-wordline 482b can be used to activate the top arm of the sub-wordline 482b shown in FIG. 3 to access data stored to column plane CP1. As another example, when the row address signal RAO is low (e.g., 0) and row address signal RA16 is high (e.g., 1), the sub-wordline driver corresponding to the sub-wordline 482b can be used to activate the bottom arm of the sub-wordline 482b shown in FIG. 3 to access data stored to column plane CP2. Similarly, when the row address signal RAO is high (e.g., 1) and the row address signal RA16 is low (e.g., 0), a sub-wordline driver corresponding to the sub-wordline 483a can be used to activate the bottom arm of the sub-wordline 483a shown in FIG. 3 to access data stored to column plane CP1. In addition, when the row address signal RAO is high (e.g., 1) and the row address signal RA16 is high (e.g., 1), a sub-wordline driver corresponding to the sub-wordline 483b can be used to activate the top arm of the sub-wordline 483b to access data stored to column plane CP2.

As still another example, when the row address signal RAO is low (e.g., 0), the row address signal RA16 is low (e.g., 0), and the first wordline 482 is fired globally, the top arms of the sub-wordlines 482b-482e can be activated to output data from all or a subset of the column planes CP1, CP3, CP5, and CP7 in parallel. On the other hand, when the row address signal RAO is low (e.g., 0), the row address signal RA16 is high (e.g., 1), and the first wordline 482 is fired globally, the bottom arms of the sub-wordlines 482a-482d can be activated to output data from all or a subset of the column plans CP0, CP2, CP4, and CP6 in parallel.

Similarly, when the row address signal RAO is high (e.g., 1), the row address signal RA16 is low (e.g., 0), and the second wordline 483 is fired globally, the bottom arms of the sub-wordlines 483a-483d can be activated to output data from all or a subset of the column planes CP1, CP3, CP5, and CP7 in parallel. On the other hand, when the row address signal RAO is high (e.g., 1), the row address signal RA16 is high (e.g., 1), and the second wordline 483 is fired globally, the top arms of the sub-wordlines 483a-483d can be activated to output data from all or a subset of the column plans CP0, CP2, CP4, and CP6 in parallel.

As discussed above, memory defects can cause errors in data written to or read from a memory array of a memory device. Thus, as described in greater detail below with reference to FIG. 6, the DQ map 480 is designed such that the data busses DQ0-DQ3 are assigned to the column planes CP0-CP7 in a specific arrangement that is expected to, in the event of a memory defect, (a) reduce and/or minimize a total number of DQs having bits with errors; and/or (b) increase the likelihood that if errors occur in bits of two DQs, the two DQs are not adjacent one another. More specifically, data path circuitry of a memory device can be used to route (i) data bus DQ3 into column planes CP0 and CP1; (ii) data bus DQ2 into column planes CP2 and CP3; (iii) data bus DQ1 into column planes CP4 and CP5; and (iv) data bus DQ0 into column planes CP6 and CP7.

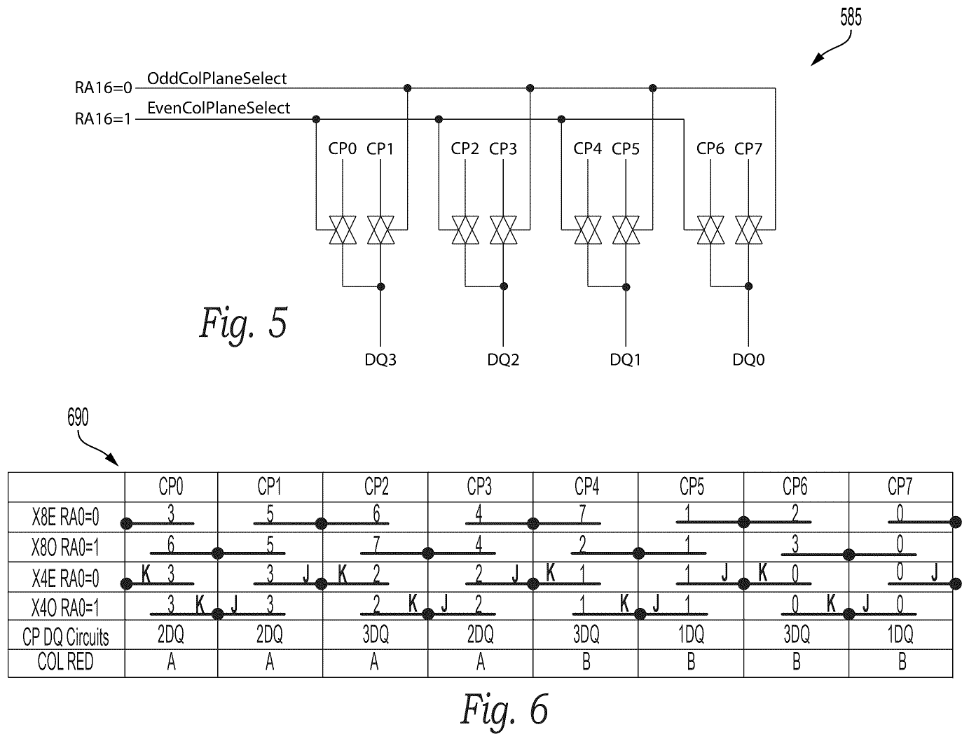

FIG. 5 is a partially schematic diagram of data routing circuitry 585 that corresponds to the DQ map 480 of FIG. 4 and that is configured in accordance with various embodiments of the present technology. In some embodiments, the data routing circuitry 585 can be an example of the control logic 157 of FIG. 1C or of other circuitry configured in accordance with various embodiments of the present technology. As shown in FIG. 5, a state of the row address signal RA16 is used to select (a) which of the column plane CP0 or the column plane CP1 is connected to the data bus DQ6; (b) which of the column plane CP2 or the column plane CP3 is connected to the data bus DQ2; (c) which of the column plane CP4 or the column plane CP5 is connected to the data bus DQ1; and (d) which of the column plane CP6 or the column plane CP7 is connected to the data bus DQ0. Thus, for each read or write access, four of the column planes CP0-CP7 are connected to the data busses DQ0-DQ3. As such, for each read or write access, data is read from or written to four of the column planes CP0-CP7.

Referring again to FIG. 4, bitlines BL0-BL7 of each of the data busses DQ0-DQ3 can be assigned to (or associated with) an even sense amp stripe 486a or an odd sense amp stripe 486b. More specifically, in the illustrated embodiment, bitlines BL0, BL2, BL1, and BL3 of each of the data busses DQ0-DQ3 can be assigned to the even sense amp stripe 486a. In addition, bitlines BL4, BL6, BL5, and BL7 of each of the data busses DQ-DQ3 can be assigned to the odd sense amp stripe 486b.

The DQ map 480 of FIG. 4 also illustrates a column redundancy repair scheme that can be employed by a memory device. In particular, as shown by the small rectangles illustrated to the right of the column plane CP0-CP3 labels in FIG. 4, if one of column planes CP0-CP3 are repaired with a redundant column, then the column repair is repeated across the other three of the column planes CP0-CP3. Similarly, as shown by the small rectangles illustrated to the right of the column plane CP4-CP7 labels in FIG. 4, if one of the column planes CP4-CP7 are repaired with a redundant column, then the column repair is repeated across the other three of the column planes CP4-CP7.

FIG. 6 is a table 690 summarizing the DQ maps 280 and 480 of FIGS. 2 and 4, respectively. Referring first to the second and third rows of the table 690, the second row of the table 690 corresponds to the top portion of the DQ map 280 illustrated in FIG. 2 (e.g., corresponding to when the row address signal RAO is low (e.g., 0) and the first wordline 282 is used to access the column planes CP0-CP7), and the third row of the table 690 corresponds to the bottom portion of the DQ map 280 illustrated in FIG. 2 (e.g., corresponding to when the row address signal RAO is high and the second wordline 283 is used to access the column planes CP0-CP7). As discussed above, the DQ map 280 can be employed by a memory device when operated in a X8 configuration.

The routings of the data busses DQ0-DQ7 provided by the DQ map 280 are expected to reduce the likelihood of SDC and UE scenarios. Referring to the second row of the table 690 as an example, when the row address signal RAO is low, the data busses DQ0-DQ7 are routed such that each of the data busses DQ0-DQ7 are routed to a respective one of the column planes CP0-CP7. Stated another way, the data busses DQ0-DQ7 are routed such that each column plane CP0-CP7 is connected to only one of the data busses DQ0-DQ7. Thus, in the event of a column select failure in one of the column planes CP0-CP7 or in the event an arm of a sub-wordline fails (also referred to herein as a weak sub-wordline fail or a SWL ARM), bit errors are expected to occur on only one of the data busses DQ0-DQ7 as a result of the column select failure or the weak sub-wordline fail. As discussed above, many error correction schemes are able to detect and correct errors that occur on only one data bus DQ. Thus, by routing a single one of the data busses DQ0-DQ7 to a respective one of the column planes CP0-CP7, the DQ map 280 is expected to increase the likelihood that bit errors that occur as a result of a column select failure and/or a weak sub-wordline fail are detectable and/or correctable. A similar advantage of the DQ map 280 is realized when the row address signal RAO is high, as shown in the third row of the table 690.

The routings of the data busses DQ0-DQ7 provided by the DQ map 280 are also expected to reduce the likelihood of SDC and UE scenarios in the event of a sub-wordline driver fail. For example, with continuing reference to the second row of the table 690, when the row address signal RAO is low, the data busses DQ0-DQ7 are routed to the column planes CP0-CP7 such that (i) the data bus DQ5 and the data bus DQ6 share a same sub-wordline of the first wordline 282, (ii) the data bus DQ4 and the data bus DQ7 share a same sub-wordline of the first wordline 282, and (iii) the data bus DQ1 and the data bus DQ2 share a same sub-wordline of the first wordline 282. Stated another way, the data bus DQ5 and the data bus DQ6 are paired, the data bus DQ4 and the data bus DQ7 are paired, and the data bus DQ1 and the data bus DQ2 are paired. Similarly, referring now to the third row of the table 690, when the row address signal RAO is high, the data busses DQ0-DQ7 are routed to the column planes CP0-CP7 such that (i) the data bus DQ6 and the data bus DQ5 share a same sub-wordline of the second wordline 283, (ii) the data bus DQ7 and the data bus DQ4 share a same sub-wordline of the second wordline 283, (iii) the data bus DQ2 and the data bus DQ1 share a same sub-wordline of the second wordline 283, and (iv) the data bus DQ3 and the data bus DQ0 share a same sub-wordline of the second wordline 283. Stated another way, the data bus DQ5 and the data bus DQ6 remain paired when the row address signal RAO is high, the data bus DQ4 and the data bus DQ7 remain paired when the row address signal RAO is high, the data bus DQ1 and the data bus DQ2 remain paired when the row address signal RAO is high, and the data bus DQ3 and the data bus DQ0 are paired when the row address signal RAO is high.

Such pairings are expected to reduce the likelihood of SDC and UEs in the event of a sub-wordline driver failure. For example, referring to the second row of the table 690, if the sub-wordline driver of the sub-wordline shared between the column plane CP3 and the column plane CP4 fails, bit errors are likely to occur on both the data bus DQ4 and the data bus DQ7. The data bus DQ4, however, (a) is not adjacent to the data bus DQ7 and (b) is of a same nibble (e.g., a second, or upper, nibble) as the data bus DQ7. Therefore, in this example, the DQ map 280 is expected (a) to limit bit errors to occurring on only two data busses DQ as a result of a sub-wordline driver failure shared by the two data busses DQ, and (b) to meet both correction conditions of the fault boundary requirement described in detail. As such, although bit errors occur on more than one (e.g., two) data busses DQ when a sub-wordline driver fails, the routings provided by the DQ map 280 for the data bus DQ4 and the data bus DQ7 are expected to increase the likelihood that bit errors on the data bus DQ4 and the data bus DQ7 as a result of the corresponding sub-wordline driver failing, are detectable and/or correctable.

Such pairings are also expected to account (or accommodate) for DQ module swizzle. For example, when DQ module swizzle is employed or enabled, a remapping of the data busses DQ can occur on the module design. More specifically, when DQ module swizzle is employed or enabled, the data busses DQ0-DQ7 can be remapped such that (i) the data bus DQ0 and the data bus DQ3 share a same sub-wordline, (ii) the data bus DQ1 and the data bus DQ2 share a same sub-wordline, (iii) the data bus DQ4 and the data bus DQ7 share a same sub-wordline, and (iv) the data bus DQ5 and the data bus DQ6 share a same sub-wordline. As shown in the second and third rows of the table 690 of FIG. 6, the DQ map 280 provides these DQ pairings regardless of the state of the row address signal RAO. Thus, the DQ map 280 can account/accommodate for DQ remapping that can occur as a result of DQ module swizzle.

Referring now to the fourth and fifth rows of the table 690, the fourth row corresponds to the DQ map 480 illustrated in FIG. 4 when the row address signal RAO is low and the first wordline 482 is used to access the column planes CP0-CP7, and the fifth row of the table 690 corresponds to the DQ map 480 when the row address signal RAO is high and the second wordline 483 is used to access the column planes CP0-CP7. As discussed above, the DQ map 480 can be employed by a memory device operated in a X4 configuration.

Similar to the DQ map 280 of FIG. 2, the routings of the data busses DQ0-DQ3 provided by the DQ map 480 are expected to (a) reduce the likelihood of SDC and UE scenarios and (b) account/accommodate for DQ remapping due to DQ module swizzle. Referring to the fourth row of the table 690 as an example, when the row address signal RAO is low, the data busses DQ0-DQ3 are routed such that each of the data busses DQ0-DQ3 are routed to a respective two of the column planes CP0-CP7. As shown, the data busses DQ0-DQ3 are routed such that each column plane CP0-CP7 is connected to only one of the data busses DQ0-DQ3. Thus, in the event of a column select failure in one of the column planes CP0-CP7 or in the event weak sub-wordline fail (SWL ARM), bit errors are expected to occur on only one of the data busses DQ0-DQ3 as a result of the column select failure or the weak sub-wordline fail. As discussed above, many error correction schemes are able to detect and correct errors that occur on only one data bus DQ. Thus, by routing a single one of the data busses DQ0-DQ3 to each of the column planes CP0-CP7, the DQ map 480 is expected to increase the likelihood that bit errors that occur as a result of a column select failure and/or a weak sub-wordline fail are detectable and/or correctable. A similar advantage of the DQ map 480 is realized when the row address signal RAO is high, as shown in the fifth row of the table 690.

The routings of the data busses DQ0-DQ3 provided by the DQ map 480 are also expected to reduce the likelihood of SDC and UE scenarios in the event of a sub-wordline driver fail. For example, with continuing reference to the fourth row of the table 690, when the row address signal RAO is low, the data busses DQ0-DQ3 are routed to the column planes CP0-CP7 such that (i) the data bus DQ3 and the data bus DQ2 share a same sub-wordline of the first wordline 482, (ii) the data bus DQ2 and the data bus DQ1 share a same sub-wordline of the first wordline 482, and (iii) the data bus DQ1 and the data bus DQ0 share a same sub-wordline of the first wordline 482. Stated another way, the data bus DQ3 and the data bus DQ2 are paired, the data bus DQ2 and the data bus DQ1 are paired, and the data bus DQ1 and the data bus DQ0 are paired.

As discussed above with reference to FIG. 4, however, a state of the row address signal RA16 is used to select which of the column planes CP0-CP7 are fired for each read or write access. This is reflected in the table 690 using “J” and “K” labels. In particular, the label “J” corresponds to the row address signal RA16 being low (e.g., 0), and the label “K” corresponds to the row address signal RA16 being high (e.g., 1). Thus, for example, when the row address signal RAO is low (e.g., 0) and the row address signal RA16 is low (e.g., 0), the column planes CP1, CP3, CP5, and CP7 are fired. On the other hand, when the row address signal RAO is low (e.g., 0) and the row address signal RA16 is high (e.g., 1), the column plans CP0, CP2, CP4, and CP6 are fired.

Because only a subset of the column planes CP0-CP7 are fired for each read or write access, a sub-wordline driver fail is expected to result in bit errors on a single one of the data busses DQ0-DQ3. For example, when the row address signal RAO is low (e.g., 0), the row address signal RA16 is low (e.g., 0), and the sub-wordline driver corresponding to column plane CP1 and column plane CP2 fails, bit errors are expected to occur on the data bus DQ3 but not on the data bus DQ2 because the column plane CP1 is fired while the column plane CP2 is not fired. As discussed above, many error correction schemes are able to detect and correct errors that occur on only one data bus DQ. Thus, by routing each of the data busses DQ0-DQ3 to two respective ones of the column planes CP0-CP7 and by firing only one side of each sub-wordline on each read or write access, the DQ map 480 is expected to increase the likelihood that bit errors that occur as a result of a sub-wordline failure are detectable and/or correctable. A similar advantage of the DQ map 480 is realized when the row address signal RAO is high, as shown in the fifth row of the table 690.

The sixth row of the table 690 in FIG. 6 indicates a total number of data bus routing circuitry implemented in the shadow of each of the column planes CP0-CP7 to implement the DQ map 280 of FIG. 2 and the DQ map 480 of FIG. 4 on a same memory device. For example, as discussed above, a memory device can be selectively operated in a X8 configuration or in a X4 configuration. When operated in the X8 configuration, the memory device can employ the DQ map 280 of FIG. 2. On the other hand, when operated in the X4 configuration, the memory device can employ the DQ map 480. Thus, to provide the flexibility of selecting which configuration (e.g., X8 or X4) in which to operate the memory device, the memory device can include data routing circuitry (e.g., control logic, multiplexers, etc.) that facilitates routing the data busses DQ0-DQ7 into corresponding column planes CP0-CP7 in accordance with the DQ map 280 and the DQ map 480.

For example, referring to column plane CP0 in the table 690, the data bus DQ3 is routed to the column plane CP0 (i) when the memory device is operated in the X8 configuration and the row address signal RAO is low and (ii) when the memory device is operated in the X4 configuration. In addition, the data bus DQ6 is routed into the column plane CP0 when the memory device is operated in the X8 configuration and the row address signal RA is high. Therefore, the memory device can include routing circuitry for two DQs (e.g., the data bus DQ3 and the data bus DQ6) in the shadow of the column plane CP0 to enable the memory device to selectively employ the DQ map 280 and the DQ map 480.

As another example, referring to column plane CP2 in the table 690, the data bus DQ6 is routed into the column plane CP2 when the memory device is operated in the X8 configuration and the row address signal RAO is low; the data bus DQ7 is routed into the column plane CP2 when the memory device is operated in the X8 configuration and the row address signal RAO is high; and the data bus DQ2 is routed into the column plane CP2 when the memory device is operated in the X4 configuration. Thus, the memory device can include routing circuitry for three DQs (e.g., the data bus DQ6, the data bus DQ7, and the data bus DQ2) in the shadow of the column plane CP2 to enable the memory device to selectively employ the DQ map 280 and the DQ map 480.

As still another example, referring to the column plane CP5, the data bus DQ1 is routed into the column plane CP5 regardless of whether the memory device is operated in the X8 configuration or the X4 configuration, and regardless of a state of the row address signal RAO. Thus, the memory device can include routing circuitry for one DQ (e.g., the data bus DQ1) in the shadow of the column plane CP5 (or the memory device can include hard programmed routing (e.g., wires) that connects the data bus DQ1 to the column plane CP5) to enable the memory device to selectively employ the DQ map 280 and the DQ map 480.

The seventh row of the table 690 reflects the redundancy repair scheme of both the DQ map 280 and the DQ map 480. As discussed above with reference to FIGS. 2 and 4, the column planes CP0-CP3 can be repaired together, and the column planes CP4-CP7 can be repaired together. As such, in the event of a column redundancy fail when the memory device is operated in the X8 configuration and employs the DQ map 280 of FIG. 2, bit errors can occur on up to four DQs (e.g., on the data bus DQ3, the data bus DQ5, the data bus DQ6, and the data bus DQ4 in the event the row address signal RAO is low and a column redundancy failure occurs in the “A” column redundancy section). Similarly, in the event of a column redundancy fail when the memory device is operated in the X4 configuration and employs the DQ map 480, bit errors can occur on up to two DQs (e.g., on the data bus DQ3 and the data bus DQ2 in the event of a failure in the “A” column redundancy section).

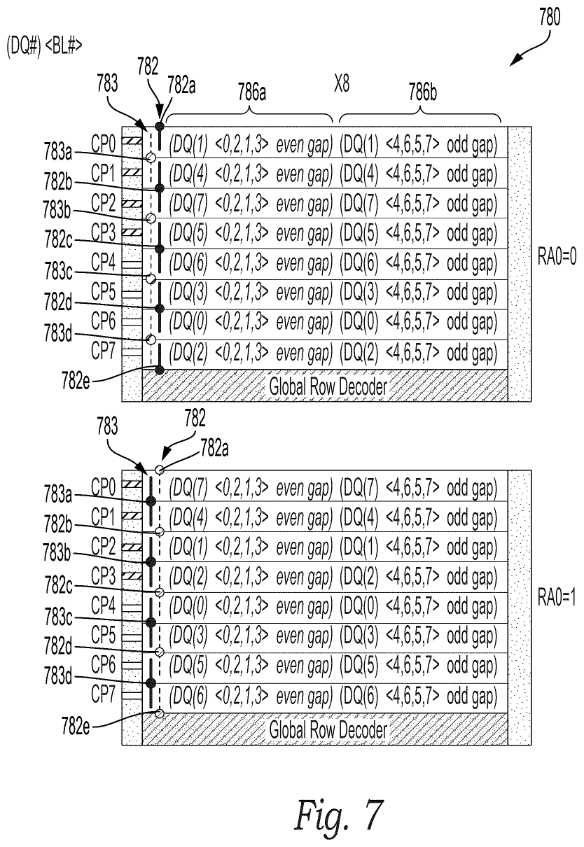

FIG. 7 is a partially schematic diagram of another DQ map 780 configured in accordance with various embodiments of the present technology. In some embodiments, the DQ map 780 can be employed by a memory device operated in a X8 configuration. For example, the DQ map 780 can be employed by a memory device (e.g., a DDR4 DRAM memory device) having a first (or lower) nibble including data busses DQ0-DQ3 and a second (or upper) nibble including data busses DQ4-DQ7. Similar to the DQ map 280 of FIG. 2 described above, the DQ map 780 can assign each of the eight data busses DQ0-DQ7 to one of eight column planes CP0-CP7.

In the illustrated embodiment, the column planes CP0-CP7 are associated with a first wordline 782 and a second wordline 783. The first wordline 782 can be used to read data from, or write data to, the column planes CP0-CP7 when a row address signal RAO received by the memory device is low (e.g., 0). The second wordline 783 can be used to read data from, or write data to, the column planes CP0-CP7 when the row address signal RAO is high (e.g., 1). The first wordline 782 can be divided into sub-wordlines 782a-782e, and the second wordline 783 can be divided into sub-wordlines 783a-783d. Each of the sub-wordlines 782a-782e and 783a-783d can correspond to a respective sub-wordline driver. The sub-wordline drivers can control data transmission to and from respective ones of the column planes CP0-CP7.

Similar to the DQ map 280 of FIG. 2 and as described in greater detail below with reference to FIG. 11, the DQ map 780 is designed such that the data busses DQ0-DQ7 are assigned to the column planes CP0-CP7 in a specific arrangement that is expected to, in the event of a memory defect, (a) reduce and/or minimize a total number of DQs having bits with errors; (b) increase the likelihood that if errors occur in bits of two DQs, the two DQs are not adjacent one another; and/or (c) increase the likelihood that if errors occur in bits of two DQs, the two DQs are of a same nibble. More specifically, when the row address signal RAO is low (e.g., 0), data path circuitry of a memory device can be used to route (i) data bus DQ1 into column plane CP0; (ii) data bus DQ4 into column plane CP1; (iii) data bus DQ7 into column plane CP2; (iv) data bus DQ5 into column plane CP3; (v) data bus DQ6 into column plane CP4; (vi) data bus DQ3 into column plane CP5; (vii) data bus DQ0 into column plane CP6; and (viii) data bus DQ2 into column plane CP7. On the other hand, when the row address signal RAO is high (e.g., 1), data path circuitry of the memory device can be used to route (i) data bus DQ7 into column plane CP0; (ii) data bus DQ4 into column plane CP1; (iii) data bus DQ1 into column plane CP2; (iv) data bus DQ2 into column plane CP3; (v) data bus DQ0 into column plane CP4; (vi) data bus DQ3 into column plane CP5; (vii) data bus DQ5 into column plane CP6; and (viii) data bus DQ6 into column plane CP7.

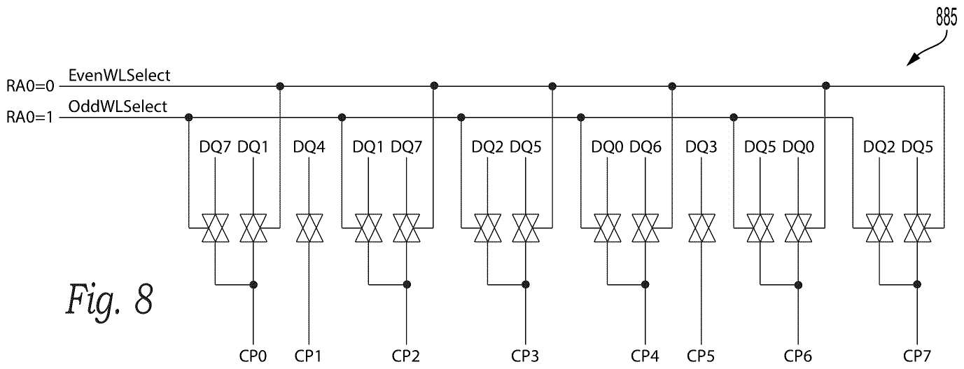

FIG. 8 is a partially schematic diagram of data routing circuitry 885 that corresponds to the DQ map 780 of FIG. 7 and that is configured in accordance with various embodiments of the present technology. In some embodiments, the data routing circuitry can be an example of the control logic 157 of FIG. 1C or of other circuitry configured in accordance with various embodiments of the present technology. As shown in FIG. 8, a state of the row address signal RAO is used to select (a) which of the data bus DQ7 or the data bus DQ1 is routed to the column plane CP0; (b) which of the data bus DQ1 or the data bus DQ7 is routed to the column plane CP2; (c) which of the data bus DQ2 or the data bus DQ5 is routed to the column plane CP3; (d) which of the data bus DQ0 or the data bus DQ6 is routed to the column plane CP4; (c) which of the data bus DQ5 or the data bus DQ0 is routed to the column plane CP6; and (f) which of the data bus DQ2 or the data bus DQ5 is routed to the column plane CP7. In the illustrated embodiment, regardless of the state of the row address signal RAO, the data bus DQ4 is routed to the column plane CP1, and the data bus DQ3 is routed to the column plane CP5.

Referring again to FIG. 7, bitlines BL0-BL7 of each of the data busses DQ0-DQ7 can be assigned to (or associated with) an even sense amp stripe 786a or an odd sense amp stripe 786b. More specifically, in the illustrated embodiment, bitlines BL0, BL2, BL1, and BL3 of each of the data busses DQ0-DQ7 can be assigned to the even sense amp stripe 786a. In addition, bitlines BL4, BL6, BL5, and BL7 of each of the data busses DQ0-DQ7 can be assigned to the odd sense amp stripe 786b.

The DQ map 780 of FIG. 7 also illustrates a column redundancy repair scheme that can be employed by a memory device. In particular, as shown by the small rectangles illustrated to the right of the column plane CP0-CP3 labels in FIG. 7, if one of column planes CP0-CP3 are repaired with a redundant column, then the column repair is repeated across the other three of the column planes CP0-CP3. Similarly, as shown by the small rectangles illustrated to the right of the column plane CP4-CP7 labels in FIG. 7, if one of the column planes CP4-CP7 are repaired with a redundant column, then the column repair is repeated across the other three of the column planes CP4-CP7.

Specific advantages of the DQ bus assignments shown in the DQ map 780 of FIG. 7 are described in greater detail below with reference to FIG. 11.

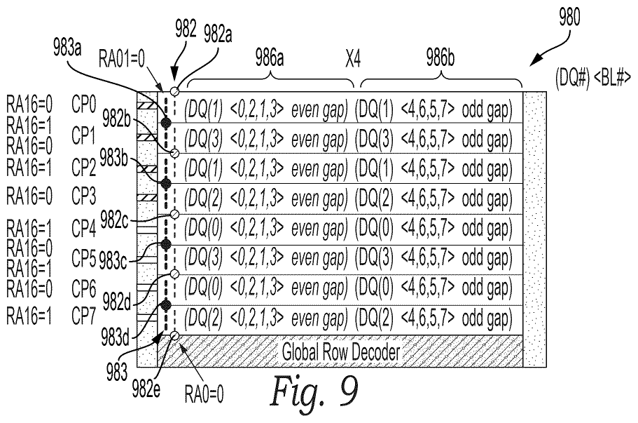

FIG. 9 is a partially schematic diagram of a DQ map 980 configured in accordance with various embodiments of the present technology. In some embodiments, the DQ map 980 can be employed by a memory device operated in a X4 configuration. For example, the DQ map 980 can be employed by a memory device (e.g., a DDR4 DRAM memory device) having a nibble including four data busses DQ0-DQ3. The memory device can be an example of the memory device described above with reference to FIG. 7 (e.g., the memory device can be selectively operated in the X8 configuration or the X4 configuration), or the memory device can be an example of other memory devices configured in accordance with various embodiments of the present technology. Similar to the DQ map 480 of FIG. 4, the DQ map 980 can assign each of the four data busses DQ0-DQ3 to two of eight column planes CP0-CP7. A state of a row address signal RA16 can determine which of the column planes CP0-CP7 are fired for each read or write access.

In the illustrated embodiment, the column planes CP0-CP7 are associated with a first wordline 982 and a second wordline 983. The first wordline 982 can be used to read data from, or write data to, the column planes CP0-CP7 when a row address signal RAO received by the memory device is low (e.g., 0). The second wordline 983 can be used to read data from, or write data to, the column planes CP0-CP7 when the row address signal RAO is high (e.g., 1). The first wordline 982 can be divided into sub-wordlines 982a-982e, and the second wordline 983 can be divided into sub-wordlines 983a-983d. Each of the sub-wordlines 982a-982e and 983a-983d can correspond to a respective sub-wordline driver. The sub-wordline drivers can control data transmission to and from respective ones of the column planes CP0-CP7. In embodiments in which the DQ map 780 of FIG. 7 and the DQ map of 980 of FIG. 9 can be employed by the same memory device, the first wordline 982 can be the first wordline 782 of FIG. 7 and/or the second wordline 983 can be the second wordline 783 of FIG. 7.

Similar to the DQ map 480 of FIG. 4, the DQ map 980 is designed such that the data busses DQ0-DQ3 are assigned to the column planes CP0-CP7 in a specific arrangement that is expected to, in the event of a memory defect, (a) reduce and/or minimize a total number of DQs having bits with errors; and/or (b) increase the likelihood that if errors occur in bits of two DQs, the two DQs are not adjacent one another. More specifically, data path circuitry of a memory device can be used to route (i) data bus DQ1 into column planes CP0 and CP2; (ii) data bus DQ3 into column planes CP1 and CP5; (iii) data bus DQ2 into column planes CP3 and CP7; and (iv) data bus DQ0 into column planes CP4 and CP6.

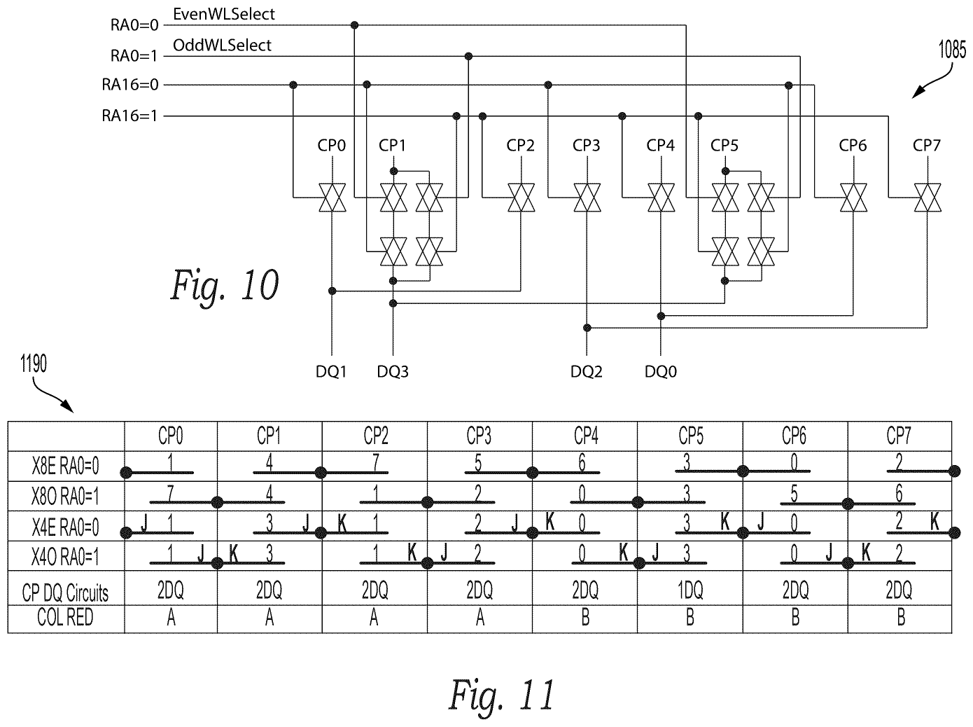

FIG. 10 is a partially schematic diagram of data routing circuitry 1085 that corresponds to the DQ map 980 of FIG. 9 and that is configured in accordance with various embodiments of the present technology. In some embodiments, the data routing circuitry 1085 can be an example of the control logic 157 of FIG. 1C or of other circuitry configured in accordance with various embodiments of the present technology. As shown in FIG. 10, a state of the row address signal RA16 is used to select (a) which of the column plane CP0 or the column plane CP2 is connected to the data bus DQ1; (b) which of the column plane CP3 or the column plane CP7 is connected to the data bus DQ2; and (c) which of the column plane CP4 or the column plane CP6 is connected to the data bus DQ0. In addition, a state of the row address signal RAO and a state of the row address signal RA16 are used to select which of the column plane CP1 or the column plane CP5 is connected to the data bus DQ3. Thus, for each read or write access, four of the column planes CP0-CP7 are connected to the data busses DQ0-DQ3. As such, for each read or write access, data is read from or written to four of the column planes CP0-CP7.

Referring again to FIG. 9, bitlines BL0-BL7 of each of the data busses DQ0-DQ3 can be assigned to (or associated with) an even sense amp stripe 986a or an odd sense amp stripe 986b. More specifically, in the illustrated embodiment, bitlines BL0, BL2, BL1, and BL3 of each of the data busses DQ0-DQ3 can be assigned to the even sense amp stripe 986a. In addition, bitlines BL4, BL6, BL5, and BL7 of each of the data busses DQ0-DQ3 can be assigned to the odd sense amp stripe 986b.

The DQ map 980 of FIG. 9 also illustrates a column redundancy repair scheme that can be employed by a memory device. In particular, as shown by the small rectangles illustrated to the right of the column plane CP0-CP3 labels in FIG. 9, if one of column planes CP0-CP3 are repaired with a redundant column, then the column repair is repeated across the other three of the column planes CP0-CP3. Similarly, as shown by the small rectangles illustrated to the right of the column plane CP4-CP7 labels in FIG. 9, if one of the column planes CP4-CP7 are repaired with a redundant column, then the column repair is repeated across the other three of the column planes CP4-CP7.

FIG. 11 is a table 1190 summarizing the DQ maps 780 and 980 of FIGS. 7 and 9, respectively. Referring first to the second and third rows of the table 1190, the second row of the table 1190 corresponds to the top portion of the DQ map 780 illustrated in FIG. 7 (e.g., corresponding to when the row address signal RAO is low (e.g., 0) and the first wordline 782 is used to access the column planes CP0-CP7), and the third row of the table 1190 corresponds to the bottom portion of the DQ map 780 illustrated in FIG. 7 (e.g., corresponding to when the row address signal RAO is high and the second wordline 783 is used to access the column planes CP0-CP7). As discussed above, the DQ map 780 can be employed by a memory device when operated in a X8 configuration.

Similar to the routings of the data busses DQ0-DQ7 provided by the DQ map 280 of FIG. 2, the routings of the data busses DQ0-DQ7 provided by the DQ map 780 of FIG. 7 are expected to reduce the likelihood of SDC and UE scenarios. For example, regardless of the state of the row address signal RAO, the data busses DQ0-DQ7 are routed in the DQ map 780 such that each column plane CP0-CP7 is connected to only one of the data busses DQ0-DQ7. Thus, in the event of a column select failure in one of the column planes CP0-CP7 or in the event an arm of a sub-wordline fails (also referred to herein as a weak sub-wordline fail or a SWL ARM), bit errors are expected to occur on only one of the data busses DQ0-DQ7 as a result of the column select failure or the weak sub-wordline fail, which is expected to increase the likelihood that bit errors that occur as a result of a column select failure and/or a weak sub-wordline fail are detectable and/or correctable.

The routings of the data busses DQ0-DQ7 provided by the DQ map 780 are also expected to reduce the likelihood of SDC and UE scenarios in the event of a sub-wordline driver fail. For example, reference to the second row of the table 1190, when the row address signal RAO is low, the data busses DQ0-DQ7 are routed to the column planes CP0-CP7 such that (i) the data bus DQ4 and the data bus DQ7 share a same sub-wordline of the first wordline 782, (ii) the data bus DQ5 and the data bus DQ6 share a same sub-wordline of the first wordline 782, and (iii) the data bus DQ3 and the data bus DQ0 share a same sub-wordline of the first wordline 782. Stated another way, the data bus DQ4 and the data bus DQ7 are paired, the data bus DQ5 and the data bus DQ6 are paired, and the data bus DQ3 and the data bus DQ0 are paired. Similarly, referring now to the third row of the table 1190, when the row address signal RAO is high, the data busses DQ0-DQ7 are routed to the column planes CP0-CP7 such that (i) the data bus DQ7 and the data bus DQ4 share a same sub-wordline of the second wordline 783, (ii) the data bus DQ1 and the data bus DQ2 share a same sub-wordline of the second wordline 783, (iii) the data bus DQ0 and the data bus DQ3 share a same sub-wordline of the second wordline 783, and (iv) the data bus DQ5 and the data bus DQ6 share a same sub-wordline of the second wordline 783. Stated another way, the data bus DQ4 and the data bus DQ7 remain paired when the row address signal RAO is high, the data bus DQ5 and the data bus DQ6 remain paired when the row address signal RAO is high, the data bus DQ3 and the data bus DQ0 remain paired when the row address signal RAO is high, and the data bus DQ1 and the data bus DQ2 are paired when the row address signal RAO is high.

Such pairings are expected to reduce the likelihood of SDC and UEs in the event of a sub-wordline driver failure. For example, referring to the second row of the table 1190, if the sub-wordline driver of the sub-wordline shared between the column plane CP1 and the column plane CP2 fails, bit errors are likely to occur on both the data bus DQ4 and the data bus DQ7. The data bus DQ4, however, (a) is not adjacent to the data bus DQ7 and (b) is of a same nibble (e.g., a second, or upper, nibble) as the data bus DQ7. Therefore, in this example, the DQ map 780 is expected (a) to limit bit errors to occurring on only two data busses DQ as a result of a sub-wordline driver failure shared by the two data busses DQ, and (b) to meet both correction conditions of the fault boundary requirement described in detail. As such, although bit errors occur on multiple (e.g., two) data busses DQ when a sub-wordline driver fails, the routings provided by the DQ map 780 for the data bus DQ4 and the data bus DQ7 are expected to increase the likelihood that bit errors on the data bus DQ4 and the data bus DQ7 as a result of the corresponding sub-wordline driver failing, are detectable and/or correctable.

Such pairings are also expected to account (or accommodate) for DQ module swizzle. For example, when DQ module swizzle is employed or enabled, a remapping of the data busses DQ can occur on the module design. More specifically, when DQ module swizzle is employed or enabled, the data busses DQ0-DQ7 can be remapped such that (i) the data bus DQ0 and the data bus DQ3 share a same sub-wordline, (ii) the data bus DQ1 and the data bus DQ2 share a same sub-wordline, (iii) the data bus DQ4 and the data bus DQ7 share a same sub-wordline, and (iv) the data bus DQ5 and the data bus DQ6 share a same sub-wordline. As shown in the second and third rows of the table 690 of FIG. 6, the DQ map 280 provides these DQ pairings regardless of the state of the row address signal RAO. Thus, the DQ map 280 can account/accommodate for DQ remapping that can occur as a result of DQ module swizzle.

Referring now to the fourth and fifth rows of the table 1190, the fourth row corresponds to the DQ map 980 illustrated in FIG. 9 when the row address signal RAO is low and the first wordline 982 is used to access the column planes CP0-CP7, and the fifth row of the table 1190 corresponds to the DQ map 980 when the row address signal RAO is high and the second wordline 983 is used to access the column planes CP0-CP7. As discussed above, the DQ map 980 can be employed by a memory device operated in a X4 configuration.

Similar to the DQ map 480 of FIG. 4, the routings of the data busses DQ0-DQ3 provided by the DQ map 980 are expected to (a) reduce the likelihood of SDC and UE scenarios (b) account/accommodate for DQ remapping due to DQ module swizzle. For example, regardless of a state of the row address signal RAO, the data busses DQ0-DQ3 are routed in the DQ map 980 such that each column plane CP0-CP7 is connected to only one of the data busses DQ0-DQ3. Thus, in the event of a column select failure in one of the column planes CP0-CP7 or in the event weak sub-wordline fail (SWL ARM), bit errors are expected to occur on only one of the data busses DQ0-DQ3 as a result of the column select failure or the weak sub-wordline fail, which is expected to increase the likelihood that bit errors that occur as a result of a column select failure and/or a weak sub-wordline fail are detectable and/or correctable.

The routings of the data busses DQ0-DQ3 provided by the DQ map 980 are also expected to reduce the likelihood of SDC and UE scenarios in the event of a sub-wordline driver fail. For example, referring to the fourth row of the table 1190, when the row address signal RAO is low, the data busses DQ0-DQ3 are routed to the column planes CP0-CP7 such that (i) the data bus DQ3 and the data bus DQ1 share a same sub-wordline of the first wordline 982, (ii) the data bus DQ2 and the data bus DQ0 share a same sub-wordline of the first wordline 982, and (iii) the data bus DQ3 and the data bus DQ0 share a same sub-wordline of the first wordline 982. Stated another way, the data bus DQ3 and the data bus DQ1 are paired, the data bus DQ2 and the data bus DQ0 are paired, and the data bus DQ3 and the data bus DQ0 are paired.

As discussed above with reference to FIGS. 4, 6, and 9, however, a state of the row address signal RA16 is used to select which of the column planes CP0-CP7 are fired for each read or write access. This is reflected in the table 690 using “J” and “K” labels. In particular, the label “J” corresponds to the row address signal RA16 being low (e.g., 0), and the label “K” corresponds to the row address signal RA16 being high (e.g., 1). Thus, for example, when the row address signal RAO is low (e.g., 0) and the row address signal RA16 is low (e.g., 0), the column planes CP0, CP1, CP3, and CP6 are fired. On the other hand, when the row address signal RAO is low (e.g., 0) and the row address signal RA16 is high (e.g., 1), the column plans CP2, CP4, CP5 and CP7 are fired.

Because only a subset of the column planes CP0-CP7 are fired for each read or write access, a sub-wordline driver fail is expected to result in bit errors on a single one of the data busses DQ0-DQ3. For example, when the row address signal RAO is low (e.g., 0), the row address signal RA16 is low (e.g., 0), and the sub-wordline driver corresponding to column plane CP1 and column plane CP2 fails, bit errors are expected to occur on the data bus DQ3 but not on the data bus DQ1 because the column plane CP1 is fired while the column plane CP2 is not fired. As discussed above, many error correction schemes are able to detect and correct errors that occur on only one data bus DQ. Thus, by routing each of the data busses DQ0-DQ3 to two respective ones of the column planes CP0-CP7 and by firing only one side of each sub-wordline on each read or write access, the DQ map 980 is expected to increase the likelihood that bit errors that occur as a result of a sub-wordline failure are detectable and/or correctable. A similar advantage of the DQ map 980 is realized when the row address signal RAO is high, as shown in the fifth row of the table 1190.

The sixth row of the table 1190 in FIG. 11 indicates a total number of data bus routing circuitry implemented in the shadow of each of the column planes CP0-CP7 to implement the DQ map 780 of FIG. 7 and the DQ map 980 of FIG. 9 on a same memory device. For example, as discussed above, a memory device can be selectively operated in a X8 configuration or in a X4 configuration. When operated in the X8 configuration, the memory device can employ the DQ map 780 of FIG. 7. On the other hand, when operated in the X4 configuration, the memory device can employ the DQ map 980 of FIG. 9. Thus, to provide the flexibility of selecting which configuration (e.g., X8 or X4) in which to operate the memory device, the memory device can include data routing circuitry (e.g., control logic, multiplexers, etc.) that facilitates routing the data busses DQ0-DQ7 into corresponding column planes CP0-CP7 in accordance with the DQ map 780 and the DQ map 980.

For example, referring to column plane CP0 in the table 690, the data bus DQ1 is routed to the column plane CP0 (i) when the memory device is operated in the X8 configuration and the row address signal RAO is low and (ii) when the memory device is operated in the X4 configuration. In addition, the data bus DQ7 is routed into the column plane CP0 when the memory device is operated in the X8 configuration and the row address signal RA is high. Therefore, the memory device can include routing circuitry for two DQs (e.g., the data bus DQ1 and the data bus DQ7) in the shadow of the column plane CP0 to enable the memory device to selectively employ the DQ map 280 and the DQ map 480.

As another example, referring to the column plane CP5, the data bus DQ3 is routed into the column plane CP5 regardless of whether the memory device is operated in the X8 configuration or the X4 configuration, and regardless of a state of the row address signal RAO. Thus, the memory device can include routing circuitry for one DQ (e.g., the data bus DQ3) in the shadow of the column plane CP5 (or the memory device can include hard programmed routing (e.g., wires) that connects the data bus DQ3 to the column plane CP5) to enable the memory device to selectively employ the DQ map 780 and the DQ map 980.

As discussed above with reference to FIG. 6, a memory device can include routing circuitry for up to three DQs for certain column planes (e.g., column plane CP2, column plane CP4, and column plane CP6) to enable the memory device to selectively employ the DQ map 280 of FIG. 2 or the DQ map 480 of FIG. 4. In comparison, a memory device can include routing circuitry for a maximum number of two DQs for each of the column planes CP0-CP7 to enable the memory device selectively employ the DQ map 780 of FIG. 7 or the DQ map 980 of FIG. 9. As such, because a memory device can include a less routing circuitry per column plane to enable the memory device to selectively employ the DQ map 780 or the DQ map 980, the DQ map 780 and the DQ map 980 can reduce or minimize a die size impact of the routing circuitry.

The seventh row of the table 1190 reflects the redundancy repair scheme of both the DQ map 780 and the DQ map 980. As discussed above with reference to FIGS. 7 and 9, the column planes CP0-CP3 can be repaired together, and the column planes CP4-CP7 can be repaired together. As such, in the event of a column redundancy fail when the memory device is operated in the X8 configuration and employs the DQ map 780 of FIG. 7, bit errors can occur on up to four DQs (e.g., on the data bus DQ1, the data bus DQ4, the data bus DQ7, and the data bus DQ5 in the event the row address signal RAO is low and a column redundancy failure occurs in the “A” column redundancy section). Similarly, in the event of a column redundancy fail when the memory device is operated in the X4 configuration and employs the DQ map 980, bit errors can occur on up to three DQs (e.g., on the data bus DQ1, on the data bus D3, and the data bus DQ2 in the event of a failure in the “A” column redundancy section when the row address signal RAO is low).

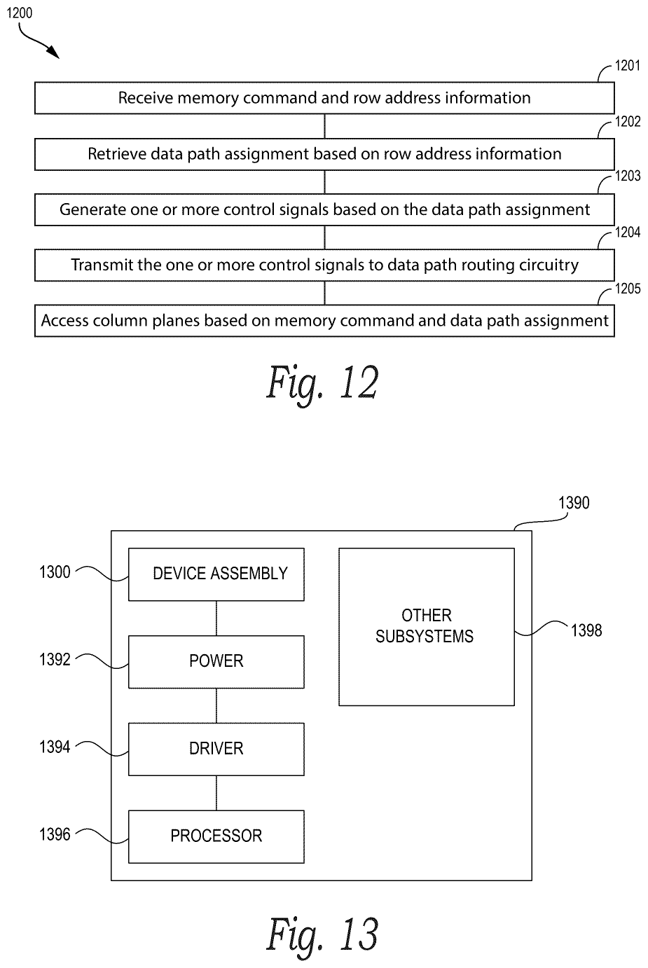

FIG. 12 is a flow diagram illustrating a method 1200 of operating a memory device in accordance with various embodiments of the present technology. The method 1200 is illustrated as a set of steps or blocks 1201-1205. All or a subset of one or more of the blocks 1201-1205 can be executed by components or devices of a memory system, such as the memory system 190 of FIG. 1A. For example, all or a subset of one or more of the blocks 1201-1205 can be executed by (i) one or more memory devices (e.g., one or more of the memory devices 100a-100h of FIGS. 1A and 1B), (ii) a memory controller (e.g., the memory controller 101 of FIG. 1A), and/or (iii) a host device (e.g., the host device 108 of FIG. 1A). Furthermore, any one or more of the blocks 1201-1205 can be executed in accordance with the discussion of FIGS. 1A-11 above.

The method 1200 begins at block 1201 by receiving a memory command and row address information. The memory command can instruct the memory device to write data to, read data from, or refresh data stored to a memory location within a memory array of the memory device. The row address information can include a row address signal RAO and/or a row address signal RA16.

At block 1202, the method 1200 continues by retrieving data path assignment information based at least in part on the row address information. For example, the method 1200 can retrieve a DQ map that specifies data path assignments based at least in part on a state of the row address signal RAO and/or on a state of the row address signal RA16. Each data path assignment can specify a mapping between a data bus DQ and a sub-wordline driver, column select, column plane, sense amp stripe, or the like of the memory device. As discussed above, the DQ map can be designed and/or implemented to help maximize data isolation and provide data groupings that avoid non-correction conditions and increase the likelihood that errors occurring as a result of memory defects can be detected and/or corrected.

At block 1203, the method 1200 continues by generating one or more control signals based at least in part on the data path assignments retrieved at block 1202. The one or more control signals can be used to multiplex at least part of a data path, such as by controlling data routing circuitry of the memory device.

At block 1204, the method 1200 continues by transmitting the one or more control signals to data path circuitry to program the data path assignments retrieved at block 1202. For example, transmitting the one or more control signals can include transmitting the one or more control signals to data routing circuitry that is usable, based on the one or more control signals, to route data busses DQs to a sub-wordline driver and/or column plane specified in the data path assignments. In some embodiments, transmitting the one or more control signals can include routing a data bus DQ from a first sub-wordline driver to a second sub-wordline driver. For example, the data bus DQ can be routed to the first sub-wordline driver when the row address signal RAO is low (e.g., 0) and can be routed to the second sub-wordline driver when the row address signal RAO is high (e.g., 1). Continuing with this example, the data bus DQ can be routed from the first sub-wordline driver to the second sub-wordline driver based at least in part on a change in the state of the row address signal RAO (e.g., from low to high).

At block 1205, the method 1200 continues by accessing column planes of the memory array based at least in part on the memory command received at block 1201 and the data path assignments implemented at block 1204. In some embodiments, accessing the column planes can include accessing the column planes based at least in part on the row address signal RA16. For example, a first subset of the column planes can be accessed with the row address signal RA16 is low (e.g., 0), and a second subset of the column planes can be access when the row address signal RA16 is high (e.g., 1). Therefore, accessing the column planes can include accessing the column planes based at least in part on a state of the row address signal RA16.

Although the blocks 1201-1205 of the method 1200 are discussed and illustrated in a particular order, the method 1200 illustrated in FIG. 12 is not so limited. In other embodiments, the method 1200 can be performed in a different order. In these and other embodiments, any of the blocks 1201-1205 of the method 1200 can be performed before, during, and/or after any of the other blocks 1201-1205 of the method 1200. Moreover, a person of ordinary skill in the relevant art will recognize that the illustrated method 1200 can be altered and still remain within these and other embodiments of the present technology. For example, one or more blocks 1201-1205 of the method 1200 illustrated in FIG. 12 can be omitted and/or repeated in some embodiments.

Any of the foregoing memory systems, devices, and/or methods described above with reference to FIGS. 1A-12 can be incorporated into any of a myriad of larger and/or more complex systems, a representative example of which is system 1390 shown schematically in FIG. 13. The system 1390 can include a semiconductor device assembly 1300, a power source 1392, a driver 1394, a processor 1396, and/or other subsystems and components 1398. The semiconductor device assembly 1300 can include features generally similar to those of the memory systems, devices, and/or methods described above with reference to FIGS. 1A-12. The resulting system 1390 can perform any of a wide variety of functions, such as memory storage, data processing, and/or other suitable functions. Accordingly, representative systems 1390 can include, without limitation, hand-held devices (e.g., mobile phones, tablets, digital readers, and digital audio players), computers, vehicles, appliances, and other products. Components of the system 1390 may be housed in a single unit or distributed over multiple, interconnected units (e.g., through a communications network). The components of the system 1390 can also include remote devices and any of a wide variety of computer readable media.

### C. CONCLUSION

As used herein, the terms “memory system” and “memory device” refer to systems and devices configured to temporarily and/or permanently store information related to various electronic devices. Accordingly, the term “memory device” can refer to a single memory die and/or to a memory package containing one or more memory dies. Similarly, the term “memory system” can refer to a system including one or more memory dies (e.g., a memory package) and/or to a system (e.g., a dual in-line memory module (DIMM)) including one or more memory packages.

Where the context permits, singular or plural terms can also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having” and “with” are used throughout to mean including at least the recited feature(s) such that any greater number of the same feature and/or additional types of other features are not precluded. Moreover, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. Some drawings may illustrate signals as a single signal; however, it will be understood by a person of ordinary skill in the art that the signal may represent a bus of signals, where the bus may have a variety of bit widths.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology, as those skilled in the relevant art will recognize. For example, while steps are presented and/or discussed in a given order, alternative embodiments can perform steps in a different order. Furthermore, the various embodiments described herein can also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology. From the foregoing, it will also be appreciated that various modifications can be made without deviating from the technology. For example, various components of the technology can be further divided into subcomponents, or that various components and functions of the technology can be combined and/or integrated. Furthermore, although advantages associated with certain embodiments of the technology have been described in the context of those embodiments, other embodiments can also exhibit such advantages, and not all embodiments need necessarily exhibit such advantages to fall within the scope of the technology. Accordingly, the disclosure and associated technology can encompass other embodiments not expressly shown or described herein.

What is claimed is:

1. A memory device, comprising:
a memory array including a plurality of column planes;
bank control circuitry including a plurality of sub-wordline drivers, wherein each sub-wordline driver of the plurality of sub-wordline drivers is associated with at least one column plane of the plurality of column planes;
data path circuitry including a plurality of data busses (DQs) and data routing circuitry, wherein the data routing circuitry is configured to couple each DQ of the plurality of DQs to a respective one of the plurality of column planes in accordance with a DQ map such that (i) each column plane of the plurality of column planes is coupled to a only one DQ at a time and (ii) bit errors resulting from a failure of one of the plurality of sub-wordline drivers occur on two DQs of a same nibble.

2. The memory device of claim 1, wherein the memory device is operable in a X8 configuration, wherein the DQ map corresponds to the X8 configuration, and wherein the data routing circuitry is configured to couple each DQ of the plurality of DQs to the respective one of the plurality of column planes in accordance with the DQ map such that bit errors resulting from the failure of the one of the plurality of sub-wordline drivers occur on two DQs that are non-adjacent one another.

3. The memory device of claim 1, wherein the memory device is selectively operable in a X4 configuration or in a X8 configuration, wherein the DQ map is a first DQ map and corresponds to the X8 configuration, and wherein the data routing circuitry is further configured to couple each DQ of a subset of the plurality of DQs to a respective two of the plurality of column planes in accordance with a second DQ map that corresponds to the X4 configuration.

4. The memory device of claim 3, wherein the data routing circuitry includes a plurality of multiplexers usable to couple the plurality of DQs to respective ones of the plurality of column planes.

5. The memory device of claim 4, wherein the first DQ map and the second DQ map are designed such that the multiplexers of the data routing circuitry are usable to selectively couple a maximum of three DQs of the plurality of DQs to each column plane of the plurality of column planes.

6. The memory device of claim 4, wherein the first DQ map and the second DQ map are designed such that the multiplexers of the data routing circuitry are usable to selectively couple a maximum of two DQs of the plurality of DQs to each column plane of the plurality of column planes.

7. The memory device of claim 1, wherein the data routing circuitry is configured to change a coupling of a first DQ of the plurality of DQs between a first column plane of the plurality of column planes and a second column plane of the plurality of column planes based at least in part on a row address signal.

8. The memory device of claim 7, wherein the data routing circuitry is configured to couple each DQ of the plurality of DQs to the respective one of the plurality of column planes in accordance with the DQ map such that the first DQ of the plurality of DQs and a second DQ of the plurality of DQs share a same sub-wordline driver regardless of a state of the row address signal.

9. The memory device of claim 7, wherein the data routing circuitry is configured to couple each DQ of the plurality of DQs to the respective one of the plurality of column planes in accordance with the DQ map such that the first DQ of the plurality of DQs and a second DQ of the plurality of DQs (i) share a same sub-wordline driver when the row address signal is in a first state and (ii) do not share a same sub-wordline driver when the row address signal is in a second state.

10. The memory device of claim 1, wherein the plurality of DQs include a sequence of first through eighth DQs DQ0-DQ7, and wherein the data routing circuitry is configured to couple each DQ of the plurality of DQs to the respective one of the plurality of column planes in accordance with the DQ map such that, for at least one state of a row address signal, (a) the fifth DQ DQ4 and the eighth DQ DQ7 share a same sub-wordline driver, (b) the second DQ DQ1 and the third DQ DQ2 share a same sub-wordline driver, (c) the sixth DQ DQ5 and the seventh DQ DQ6 share a same sub-wordline driver, and (d) the fourth DQ DQ4 and the first DQ DQ0 share a same sub-wordline driver.

11. The memory device of claim 1, wherein the plurality of DQs include a sequence of first through eighth DQs DQ0-DQ7, and wherein the data routing circuitry is configured to couple each DQ of the plurality of DQs to the respective one of the plurality of column planes in accordance with the DQ map such that, for at least one state of a row address signal, (a) the sixth DQ DQ5 and the seventh DQ DQ6 share a same sub-wordline driver, (b) the fifth DQ DQ4 and the eighth DQ DQ7 share a same sub-wordline driver, (c) the second DQ DQ1 and the third DQ DQ2 share a same sub-wordline driver, and (d) the first DQ DQ0 and the fourth DQ DQ3 share a same sub-wordline driver.

12. The memory device of claim 1, wherein the memory device is configured to fire a subset of the plurality of column planes representing less than all of the plurality of column planes and based at least in part on a state of a row address signal.

13. The memory device of claim 1, wherein the memory device is a double data rate fourth-generation (DDR4) dynamic random-access memory (DRAM) device.

14. A method, comprising:
receiving a memory command and row address information;
retrieving data path assignments based at least in part on the row address information; and
coupling each data bus (DQ) of a plurality of DQs of a memory device to a respective one of a plurality of column planes of the memory device in accordance with the data path assignments such that (i) each column plane of the plurality of column planes is coupled to a only one DQ at a time and (ii) bit errors resulting from a failure of a sub-wordline driver associated with two of the plurality of column planes occurs on two DQs of a same nibble.

15. The method of claim 14, wherein the data path assignments correspond to a X8 configuration of the memory device, and wherein coupling each DQ of the plurality of DQs to the respective one of the plurality of column planes in accordance with the data path assignments includes coupling each DQ of the plurality of DQs to the respective one of the plurality of column planes such that bit errors resulting from the failure of the sub-wordline driver occur on two DQs that are non-adjacent one another.

16. The method of claim 14, wherein coupling each DQ of the plurality of DQs to the respective one of the plurality of column planes in accordance with the data path assignments includes changing a coupling of a first DQ of the plurality of DQs between a first column plane of the plurality of column planes and a second column plane of the plurality of column planes based at least in part on a row address signal.

17. The method of claim 14, further comprising firing a subset of the plurality of column planes representing less than all of the plurality of column planes and based at least in part on a state of a row address signal.

18. A memory system, comprising:
a host device; and
a memory device operably coupled to the host device, wherein the memory device includes a memory array including a plurality of column planes,
bank control circuitry including a plurality of sub-wordline drivers, wherein each sub-wordline driver of the plurality of sub-wordline drivers is associated with at least one column plane of the plurality of column planes, and
data path circuitry including a plurality of data busses (DQs) and data routing circuitry, wherein the data routing circuitry is configured to couple each DQ of the plurality of DQs to a respective one of the plurality of column planes in accordance with a DQ map, wherein the DQ map provides data path assignments for the memory device when the memory device is operated in a X8 configuration or a X4 configuration, and wherein the data path assignments are based at least in part on correction conditions of error correction components of the host device or of the memory device and ensure that (i) each column plane of the plurality of column planes is coupled to a only one DQ at a time, and (ii) bit errors resulting from a failure of one of the plurality of sub-wordline drivers occur on two DQs of a same nibble.

19. The memory system of claim 18, wherein the data path assignments of the DQ map, at least when the memory device is operated in the X8 configuration, ensure that bit errors resulting from the failure of the one of the plurality of sub-wordline drivers occur on two DQs that are non-adjacent one another.

20. The memory system of claim 18, wherein the data routing circuitry includes a plurality of multiplexers usable to couple the plurality of DQs to respective ones of the plurality of column planes based on (i) first data path assignments that correspond to the X4 configuration and (ii) second data path assignments corresponding to the X8 configuration, and wherein the first and second data path assignments are designed such that the multiplexers of the data routing circuitry are usable to selectively couple a maximum of two DQs of the plurality of DQs to each column plane of the plurality of column planes.
